(19) United States
(12) Patent Application Publication
(10) Pub. No.: US 2025/0241069 A1
(43) Pub. Date: Jul. 24, 2025

(54) BIPOLAR JUNCTION TRANSISTOR WITH ADJUSTABLE GAIN

(71) Applicant: AMAZING MICROELECTRONIC CORP., New Taipei City (TW)

(72) Inventors: Chih-Ting YEH, Zhudong Township (TW); Sung-Chih HUANG, Jiaoxi Township (TW); Che-Hao CHUANG, Jhudong Township (TW); Kun-Hsien LIN, Hsinchu City (TW)

(73) Assignee: AMAZING MICROELECTRONIC CORP., New Taipei City (TW)

(21) Appl. No.: 18/417,238

(22) Filed: Jan. 19, 2024

(51) Int. Cl. H01L 27/02

(52) U.S. Cl. CPC H10D 89/711

(57) ABSTRACT

A bipolar junction transistor with adjustable gain is provided, including a semiconductor substrate and doped layer of a first conductivity type, a doped well region of a second conductivity type and a plurality of heavily doped regions. At least one detection circuit is provided with an input voltage and operable to generate an output voltage for a conducting layer to receive, such that current paths generated in the transistor can be determined when the input voltage varies under different operating conditions, including a normal operating mode, a positive and a negative surged operating mode. When a transient event takes place, the bipolar junction transistor is characterized by having a higher gain than it is operating in the normal mode. The proposed invention achieves in integrating the unidirectional and bidirectional electrical characteristics in the disclosed bipolar junction transistor structure by employing the detection circuit such that adjustable gain is obtained.

### BACKGROUND OF THE INVENTION

### Field of the Invention

The present disclosure is related to a bipolar junction transistor design scheme. And more particularly, it is related to a bipolar junction transistor structure which is characterized by having at least one detection circuit such that a gain of the provided bipolar junction transistor is adjustable under different operating conditions.

### Description of the Prior Art

As known, a transient voltage suppressor or known as a “TVS” is a general classification of electronic components that are designed to react to sudden or momentary overvoltage conditions. One such common device used for this purpose is known as the transient voltage suppression diode, a Zener diode designed to protect electronics device against over-voltages. In general, the characteristic of a transient voltage suppressor (TVS) requires that it responds to over-voltages faster than other common overvoltage protection components such as varistors or gas discharge tubes. Such characteristic of the TVS device or component makes it much more useful for protection against extremely fast and often damaging voltage spikes, since these fast overvoltage spikes are present on all distribution networks and can be caused by either internal or external events, such as lightning or motor arcing. In addition, applications of the transient voltage suppression devices are able to be used for unidirectional or bidirectional electrostatic discharge (ESD) protection of transmission or data lines in electronic circuits. Usually, the level of the ESD energy in a transient overvoltage can be equated to energy measured in joules or related to electric current when devices are rated for various applications. These bursts of overvoltage can be measured with specialized electronic meters that can show power disturbances of thousands of volts amplitude that last for a few microseconds or less.

FIG. 1 shows a conventional bidirectional bipolar junction transistor (BJT) structure, comprising an N-type substrate 10, an N-type layer 12, a P-type well 14, and a plurality of N-type heavily doped regions 161, 162, 163 disposed in the P-type well 14. The N-type heavily doped region 161 is electrically coupled with a high voltage level VH, and the N-type heavily doped regions 162 and 163 are electrically coupled in common and with a low voltage level VL. As can be seen in the figure, the P-type well 14 is floating, indicating that the base of the lateral n-p-n BJT, illustrated by dashed lines in FIG. 1, is floating. FIG. 2 shows a conventional unidirectional bipolar junction transistor (BJT) structure in view of FIG. 1, which further comprises a plurality of P-type heavily doped regions 164 and 165 disposed in the P-type well 14 in addition to the above mentioned N-type heavily doped regions 161, 162 and 163 in FIG. 1. In such a modified bipolar junction transistor structure, it is apparent that the P-type heavily doped regions 164, 165 as well as the N-type heavily doped regions 162, 163 are electrically coupled in common and with the low voltage level VL, while the N-type heavily doped region 161 is electrically coupled with the high voltage level VH. As can be seen in the figure, the P-type well 14 is directly connected to the low voltage level VL in FIG. 2, and when a negative surged pulse is injected, the p-n forward diodes, illustrated by dashed lines in FIG. 2, are thus formed.

In addition, FIG. 3 shows one another conventional unidirectional bipolar junction transistor (BJT) structure in the prior art. In addition to the above mentioned N-type substrate 10, the N-type layer 12, the P-type well 14, and the N-type heavily doped regions 161, 162, 163 disposed in the P-type well 14, a P-type heavily doped region 171 and a P-type heavily doped region 172 are further disposed in the P-type well 14. The P-type heavily doped region 171 is electrically connected with an N-type heavily doped region 181 which is disposed in the N-type layer 12. And the P-type heavily doped region 172 is electrically connected with another N-type heavily doped region 182 which is disposed in the N-type layer 12. And a P-type heavily doped region 191 is further disposed in the N-type layer 12 and electrically connected with the N-type heavily doped regions 162 and 163. Another P-type heavily doped region 192 is also disposed in the N-type layer 12 and electrically connected with the N-type heavily doped regions 162 and 163. And the P-type heavily doped regions 191, 192 as well as the N-type heavily doped regions 162, 163 are coupled in common and electrically with the low voltage level VL. As can be seen in the unidirectional bipolar junction transistor (BJT) structure in FIG. 3, under such a configuration, it is apparent that the N-type layer 12 and the P-type well 14 are thus having the same voltage potential. However, it is, on the other hand, noticeable that a greatly increased trigger voltage of such bipolar junction transistor (BJT) structure is accordingly observed, thereby affect its electrostatic discharge (ESD) performance. As known, such a significantly lowered electrostatic discharge performance is definitely not what to be expected. And as a result, based on the foregoing drawbacks and necessary suppression and elimination of the conventional issues are thus to be solved, it, in view of all, should be apparent and obvious that there is indeed an urgent need for the professionals in the field for a novel and inventive transistor structure to be developed, so as to solve the above-mentioned issues occurring in the prior arts.

In response to the foregoing issues to be solved, the full detailed specific descriptions and implementations are now to be provided in particular, by the Applicants of the present invention in the following paragraphs as below for people skilled in the related art to acknowledge and take for references.

### SUMMARY OF THE INVENTION

In order to overcome the above-mentioned disadvantages, one major objective in accordance with the present invention is provided for a novel and creative circuit scheme for providing a bipolar junction transistor structure. And more particularly, the proposed circuit scheme of the disclosed bipolar junction transistor structure is characterized by having an adjustable gain under different operating conditions. And the present invention is advantageous of being fabricated without the needs of additional process steps and no circuit complexity is to be increased.

Another objective in accordance with the present invention is to provide for a novel bipolar junction transistor structure with adjustable gain, in which at least one detection circuit is employed to receive an input voltage and operable to generate an output voltage for determining the current path generating in the provided bipolar junction transistor structure. When the input voltage is supplied with a power supply voltage (VDD), the generated output voltage is at a higher voltage level than the output voltage is when the input voltage is provided with a transient event. According to the embodiment of the present invention, the transient event may be a positive voltage level so as to provide a positive surged operating mode. Alternatively, the transient event may alternatively be a negative voltage level so as to provide a negative surged operating mode. By employing such circuit configuration, it is believed that, by employing the present invention, the disclosed bipolar junction transistor structure is able to have a higher gain when the positive or negative surged operating mode is applied. On the contrary, under a normal operating mode, in which when the input voltage is supplied with the power supply voltage (VDD), then the disclosed bipolar junction transistor structure is comparably having a lower gain. As a result, it is believed that the bipolar junction transistor structure having an adjustable gain is thus formed in the present invention.

In one embodiment, the disclosed detection circuit can be implemented by using a resistor. And yet, the present invention is not limited thereto. According to another feasible embodiment of the present invention, then the disclosed detection circuit may also be implemented by using a Zener diode, a resistor and an inverter. In detailed configurations, one end of the Zener diode is electrically connected with the input voltage while another end of the Zener diode is connected with the resistor, the resistor is further connected to a ground terminal, and one end of the inverter is electrically connected with a joint end where the Zener diode and the resistor are connected while another end of the inverter is operable to generate the output voltage.

In the following descriptions, the Applicants will proceed to provide a plurality of embodiments and variations that will be discussed later in the following paragraphs in order to verify the proposed bipolar junction transistor structure with adjustable gain is effective. Thereby, it is worthy of full attentions that the present invention achieves to successfully solve the problems of prior arts and meanwhile maintain superior electrical properties. As a result, it is believed that the proposed technical contents of the present invention are extremely advantageous of as being highly competitive and able to be widely utilized in related IC and semiconductor industries.

Therefore, in order to achieve the above-mentioned objectives, the present invention is aimed to provide a modified bipolar junction transistor structure which has an adjustable gain that is to be introduced as follows.

According to the present invention, the bipolar junction transistor having adjustable gain includes: a semiconductor substrate of a first conductivity type, a doped layer of the first conductivity type which is formed on the semiconductor substrate of the first conductivity type, a doped well region of a second conductivity type which is formed in the doped layer of the first conductivity type, and a first heavily doped region of the second conductivity type, a second heavily doped region of the second conductivity type, a third heavily doped region of the first conductivity type, a fourth heavily doped region of the first conductivity type and a fifth heavily doped region of the first conductivity type which are disposed in the doped well region of the second conductivity type. According to the embodiment of the present invention, the second conductivity type is opposite to the first conductivity type.

In one embodiment, when the first conductivity type is an N type, the second conductivity type is a P type. Alternatively, in an alternative embodiment of the present invention, when the first conductivity type is a P type, then the second conductivity type will alternatively be an N type. The present invention is not limited to the certain conductivity type to be disposed in the circuit diagram structure. In other words, a plurality of alternative variations and embodiments may also be made determined and fabricated by people who are skilled in the art and having ordinary skills of the art. And yet, the present invention still covers the modifications and its equality based on the disclosed technical contents of the present invention.

According to the present invention, the fifth heavily doped region of the first conductivity type is electrically coupled with a first pin, while the third heavily doped region of the first conductivity type and the fourth heavily doped region of the first conductivity type are electrically connected in common and coupled with a second pin. By configurations, the first heavily doped region of the second conductivity type and the second heavily doped region of the second conductivity type are spaced apart by the third heavily doped region of the first conductivity type, the fourth heavily doped region of the first conductivity type and the fifth heavily doped region of the first conductivity type.

Moreover, a sixth heavily doped region is further disposed and is electrically connected with the first heavily doped region of the second conductivity type. A seventh heavily doped region is further disposed and is electrically connected with the second heavily doped region of the second conductivity type. An eighth heavily doped region which is disposed adjacent to the sixth heavily doped region and a ninth heavily doped region which is disposed adjacent to the seventh heavily doped region are further provided and coupled with the above mentioned second pin.

The disclosed bipolar junction transistor structure is aimed to provide and dispose at least one detection circuit for controlling and adjusting the gain of the bipolar junction transistor structure. According to the embodiment of the present invention, the disclosed detection circuit may comprise a first detection circuit which is disposed between the sixth heavily doped region and the eighth heavily doped region, and a second detection circuit which is disposed between the seventh heavily doped region and the ninth heavily doped region. In specific, each of the first detection circuit and the second detection circuit is provided with an input voltage for being operable to generate a first output voltage and a second output voltage, respectively. And a first conducting layer receiving the first output voltage is disposed between the sixth heavily doped region and the eighth heavily doped region, and a second conducting layer receiving the second output voltage is disposed between the seventh heavily doped region and the ninth heavily doped region for determining at least one current path generated in the disclosed bipolar junction transistor structure when the input voltage varies under different operating conditions. As a result, it is believed that by such configurations, the disclosed bipolar junction transistor structure of the present invention having an adjustable gain is effectively formed.

According to one embodiment of the present invention, either the first detection circuit or the second detection circuit can be implemented by using a resistor. For instance, the first detection circuit or the second detection circuit may be a detecting device, such as a poly resistor, or a well-region resistor.

On the other hand, according to one another preferred embodiment of the present invention, then either the first detection circuit or the second detection circuit may alternatively be implemented by using a circuit diagram, comprising a Zener diode, a resistor and an inverter. In detailed configurations, one end of the Zener diode is electrically connected with the input voltage while another end of the Zener diode is connected with the resistor, the resistor is further connected to a ground terminal, and one end of the inverter is electrically connected with a joint end where the Zener diode and the resistor are connected while another end of the inverter is operable to generate the first output voltage or the second output voltage.

In addition, regarding the first conducting layer and the second conducting layer which are respectively connected to the first detection circuit and the second detection circuit for receiving the first output voltage and the second output voltage, either the first conducting layer or the second conducting layer can be implemented by using a poly or a metal gate.

As a result, each of the first conducting layer and the second conducting layer is operable so as to determine the current path generated in the disclosed bipolar junction transistor structure when the input voltage varies under different operating conditions, including a normal operating mode, a positive surged operating mode and a negative surged operating mode in which a transient event occurs. As a result, it is believed that by such configurations, the disclosed bipolar junction transistor structure with an adjustable gain is thus formed by the technical solution of the present invention.

To be more specifically speaking, when the input voltage is coupled with a power supply voltage (VDD), under such a normal operating mode in which the first detection circuit and the second detection circuit generate the first output voltage and the second output voltage as the power supply voltage (VDD), then it is verified that the disclosed bipolar junction transistor structure is having a first gain (g1).

And on the other hand, when there is a transient event occurs, indicating that the input voltage is coupled with a positive voltage level or a negative voltage level so as to provide a positive surged operating mode or a negative surged operating mode, then under such a positive or negative surged operating mode, the first detection circuit and the second detection circuit accordingly generate the first output voltage and the second output voltage having a virtual ground voltage. Under such an operating mode, in which a transient event occurs, then the disclosed bipolar junction transistor structure is having a second gain (g2) instead. According to the embodiment of the present invention, it is verified that the second gain of the bipolar junction transistor structure is greater than the above mentioned first gain, indicating that: g2>g1. As a result, the bipolar junction transistor with adjustable gain of the present invention is effectively obtained by employing the technical contents and circuit configurations as proposed in the present invention.

To sum up, it should be noted that according to the foregoing disclosed technical contents provided by the Applicants of the present invention, the present invention is certainly not limited thereto by the above-mentioned embodiments. In other words, for people who are skilled in the art and having ordinary understandings and technical backgrounds to the present invention, it would be allowed for people skilled in the art to make various modifications or changes depending on different circuit regulations and/or specifications without departing from the scope of the invention. That is to say, the present invention is certainly not limited thereto. And the variant embodiments and/or circuit implementations should still fall into the claim scope of the present invention.

And yet, in another aspect, the Applicants of the present invention further propose a bipolar junction transistor with adjustable gain. According to the disclosed bipolar junction transistor structure, the bipolar junction transistor with adjustable gain includes a semiconductor substrate, a doped layer, a doped well region, a third heavily doped region, a fourth heavily doped region, a fifth heavily doped region, a tenth heavily doped region, an eleventh heavily doped region, a twelfth heavily doped region, a thirteenth heavily doped region, a first detection circuit, a second detection circuit, a first conducting layer and a second conducting layer.

According to the embodiment of the present invention, the semiconductor substrate has a first conductivity type, the doped layer has the first conductivity type and the doped layer of the first conductivity type is formed on the semiconductor substrate of the first conductivity type. The doped well region has a second conductivity type, the doped well region of the second conductivity type is formed in the doped layer of the first conductivity type, and the second conductivity type is opposite to the first conductivity type.

The third heavily doped region, the fourth heavily doped region and the fifth heavily doped region has the first conductivity type. And the third heavily doped region of the first conductivity type, the fourth heavily doped region of the first conductivity type and the fifth heavily doped region of the first conductivity type are further disposed in the doped well region of the second conductivity type. The fifth heavily doped region of the first conductivity type is electrically coupled with a first pin. And the third heavily doped region of the first conductivity type and the fourth heavily doped region of the first conductivity type are electrically connected in common and coupled with a second pin.

The tenth heavily doped region has the second conductivity type, the eleventh heavily doped region has the first conductivity type, the twelfth heavily doped region has the second conductivity type and the thirteenth heavily doped region has the first conductivity type. The tenth heavily doped region of the second conductivity type and the eleventh heavily doped region of the first conductivity type are electrically connected in common. The twelfth heavily doped region of the second conductivity type and the thirteenth heavily doped region of the first conductivity type are electrically connected in common. And the tenth heavily doped region of the second conductivity type, the eleventh heavily doped region of the first conductivity type, the twelfth heavily doped region of the second conductivity type and the thirteenth heavily doped region of the first conductivity type are further disposed in the doped well region of the second conductivity type.

According to such an embodiment, the tenth heavily doped region of the second conductivity type and the eleventh heavily doped region of the first conductivity type are disposed on one side of the third heavily doped region of the first conductivity type, the fourth heavily doped region of the first conductivity type and the fifth heavily doped region of the first conductivity type. And on the other hand, the twelfth heavily doped region of the second conductivity type and the thirteenth heavily doped region of the first conductivity type are disposed on an opposite side of the third heavily doped region of the first conductivity type, the fourth heavily doped region of the first conductivity type and the fifth heavily doped region of the first conductivity type.

The first detection circuit is provided and disposed between the eleventh heavily doped region of the first conductivity type and the third heavily doped region of the first conductivity type, and the second detection circuit is provided and disposed between the thirteenth heavily doped region of the first conductivity type and the fourth heavily doped region of the first conductivity type. In addition, each of the first detection circuit and the second detection circuit is provided with an input voltage for being operable to respectively generate a first output voltage and a second output voltage for the first conducting layer and the second conducting layer to receive. By such configurations, the first conducting layer receiving the first output voltage is disposed between the eleventh heavily doped region of the first conductivity type and the third heavily doped region of the first conductivity type, and the second conducting layer receiving the second output voltage is disposed between the thirteenth heavily doped region of the first conductivity type and the fourth heavily doped region of the first conductivity type. By employing the above mentioned first detection circuit, the second detection circuit along with the first conducting layer and the second conducting layer, it is derived that at least one current path when the input voltage varies under different operating conditions can be determined such that the bipolar junction transistor having adjustable gain is formed.

According to such an embodiment of the present invention, it is implemented that the input voltage is electrically connected with the first pin where the fifth heavily doped region of the first conductivity type is electrically coupled thereto.

Regarding the detailed configuration layouts, it is practicable to retain a first spacing to be formed between the tenth heavily doped region of the second conductivity type and the eleventh heavily doped region of the first conductivity type. By adopting the same design manners, it may also be practicable to retain a second spacing to be formed between the twelfth heavily doped region of the second conductivity type and the thirteenth heavily doped region of the first conductivity type. However, the present invention is certainly not limited thereto. From the perspective of further reducing layout area consumption, then the above mentioned first spacing and/or second spacing may be omitted as well.

That is to say, in other words, according to variant alternative embodiments of the present invention, then the tenth heavily doped region of the second conductivity type and the eleventh heavily doped region of the first conductivity type may be disposed seamlessly adjacent to each other. And, the twelfth heavily doped region of the second conductivity type and the thirteenth heavily doped region of the first conductivity type may also be disposed seamlessly adjacent to each other in order to further reduce redundant area waste for circuit layout consumption.

According to one embodiment, when the first conductivity type is an N type and the second conductivity type is a P type, it is believed that the first pin, the second pin, and the input voltage are electrically coupled to a high voltage level, a low voltage level, and the first pin, respectively.

On the contrary, according to another embodiment of the present invention, when the first conductivity type is a P type and the second conductivity type is an N type, then the first pin, the second pin, and the input voltage are electrically coupled to a low voltage level, a high voltage level, and the first pin, respectively.

Furthermore, according to the embodiment of the present invention, either the first detection circuit or the second detection circuit can be implemented by using a resistor. For instance, the first detection circuit or the second detection circuit may be a detecting device, such as a poly resistor, or a well-region resistor.

In another aspect, according to one another preferred embodiment of the present invention, then either the first detection circuit or the second detection circuit may alternatively be implemented by using a circuit diagram, which is composed of a Zener diode, a resistor and an inverter. Regarding detailed configurations, it is implemented to design one end of the Zener diode being electrically connected with the input voltage while another end of the Zener diode is connected with the resistor. The resistor is further connected to a ground terminal, and one end of the inverter is electrically connected with a joint end where the Zener diode and the resistor are connected while another end of the inverter is operable to generate the first output voltage or the second output voltage.

In addition, regarding the first conducting layer and the second conducting layer which are respectively connected to the first detection circuit and the second detection circuit for receiving the first output voltage and the second output voltage, either the first conducting layer or the second conducting layer can be implemented by using a poly or a metal gate.

As a result, each of the first conducting layer and the second conducting layer is operable so as to respectively receive the first output voltage and the second output voltage and to determine the current path generated in the disclosed bipolar junction transistor structure when the input voltage varies under different operating conditions, including a normal operating mode, a positive surged operating mode and a negative surged operating mode in which a transient event occurs. As a result, it is believed that by such configurations, the disclosed bipolar junction transistor structure with an adjustable gain is thus formed by the proposed bipolar junction transistor structure of the present invention.

In general, those skilled in the art and having general knowledge are able to make appropriate modifications or variations with respective to the technical contents disclosed in the present invention without departing from the spirits of the present invention. The present invention is not restricted by the certain limited configurations and/or circuit diagrams disclosed in the embodiments of the present invention. As such, it is believed that the modifications or variations should still fall into the scope of the present invention, and the present invention covers the modifications and its equality.

In general, when the input voltage is coupled with a power supply voltage (VDD), then the first detection circuit and the second detection circuit generate the first output voltage and the second output voltage as the power supply voltage, and the bipolar junction transistor with adjustable gain has a first gain. And when the input voltage is coupled with a positive voltage level so as to provide a positive surged operating mode, the first detection circuit and the second detection circuit generate the first output voltage and the second output voltage having a virtual ground voltage, and the bipolar junction transistor with adjustable gain has a second gain. It is believed that the second gain is greater than the first gain.

While considering a negative surged operating mode, when the input voltage is coupled with a power supply voltage (VDD), the first detection circuit and the second detection circuit generate the first output voltage and the second output voltage as the power supply voltage, and the bipolar junction transistor with adjustable gain has a first gain. And on the other hand, when the input voltage is coupled with a negative voltage level so as to provide the negative surged operating mode, then the first detection circuit and the second detection circuit generate the first output voltage and the second output voltage having a virtual ground voltage, and the bipolar junction transistor with adjustable gain has a second gain. It is believed that the second gain is greater than the first gain.

As a result, based on the disclosed technical features illustrated as above, it is evident that the present invention is sophisticatedly designed and indeed discloses a novel modified scheme for a new bipolar junction transistor structure to be developed with an adjustable gain is to be provided. The proposed invention regarding a plurality of feasible embodiments, is characterized by adopting at least one detection circuit and at least one conducting layer so as to determine the current paths generated in view of different operating conditions, including a normal operating mode, a positive surged operating mode and a negative surged operating mode when the input voltage varies. As a result, it is obtained that a gain of the provided bipolar junction transistor can be preferably adjustable under different operating conditions. And thus, by adopting the present invention, it is believed that the present invention achieves in effectively eliminating the conventional drawback issues occurring in the prior arts. In addition, since the first pin and the second pin connected thereto by the present invention, are disposed on a same surface of the bipolar junction transistor structure, it can also be obtained that the traditional backside metallization process in the prior arts can be omitted at the same time. And therefore, the circuit complexity for implementing such the disclosed bipolar junction transistor structure can also be made to be relatively low.

As a result, it is believed that the proposed bipolar junction transistor having adjustable gain disclosed by the present invention, is beneficial in view of a great number of merits. Thus, it is believed that the present invention is extremely advantageous while compared to the prior arts.

These and other objectives of the present invention will become obvious to those of ordinary skill in the art after reading the following detailed description of preferred embodiments. And it is to be understood that both the foregoing general description and the following detailed description are exemplary and are intended to provide further explanation of the invention as claimed.

### BRIEF DESCRIPTION OF THE DRAWINGS

The accompanying drawings are included to provide a further understanding of the invention and are incorporated in and constitute a part of this specification. The drawings illustrate embodiments of the invention and, together with the description, serve to explain the principles of the invention. In the drawings:

FIG. 1 schematically shows a conventional bidirectional bipolar junction transistor (BJT) structure in the prior art.

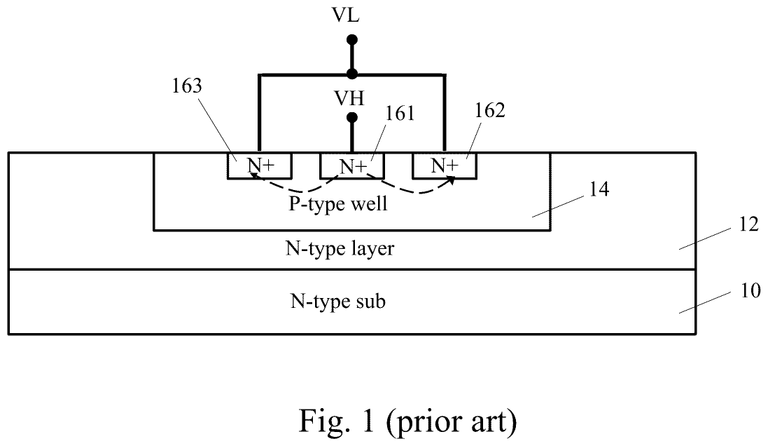

FIG. 2 schematically shows a conventional unidirectional bipolar junction transistor (BJT) structure in view of FIG. 1 in the prior art.

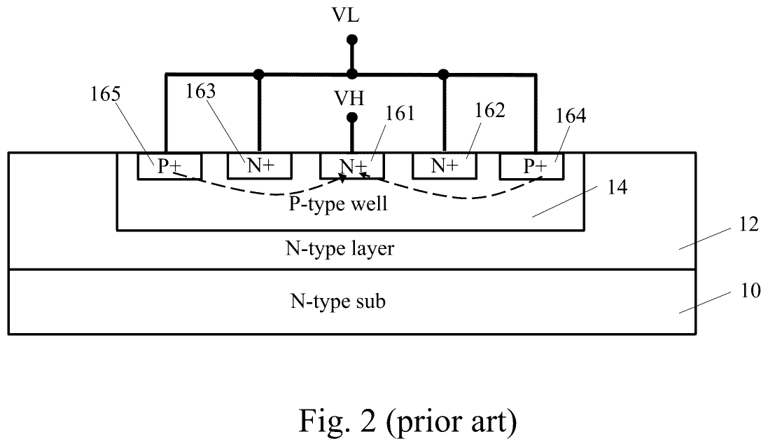

FIG. 3 schematically shows one another conventional unidirectional bipolar junction transistor (BJT) structure in the prior art.

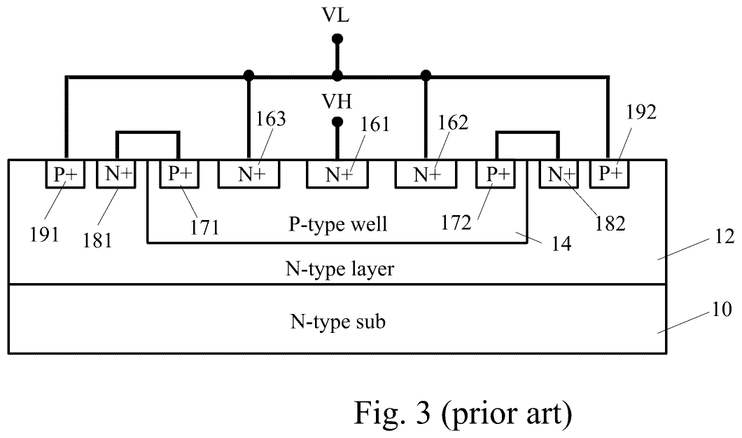

FIG. 4 schematically shows a structural diagram of a proposed bipolar junction transistor with adjustable gain in accordance with a first embodiment of the present invention.

FIG. 5 schematically shows one feasible circuit diagram for implementing the disclosed detection circuit of the present invention when the detection circuit is a device or is a component.

FIG. 6 schematically shows one another feasible circuit diagram for implementing the disclosed detection circuit of the present invention when the detection circuit is a circuit diagram.

FIG. 7 shows an illustrative diagram, indicating that the bipolar junction transistor is operating in a normal operating mode according to the FIG. 4 and FIG. 5 structural embodiment.

FIG. 8 shows an illustrative diagram, indicating that the bipolar junction transistor is operating in a positive surged operating mode according to the FIG. 4 and FIG. 5 structural embodiment.

FIG. 9 shows an illustrative diagram, indicating that the bipolar junction transistor is operating in a negative surged operating mode according to the FIG. 4 and FIG. 5 structural embodiment.

FIG. 10 schematically shows a structural diagram of a proposed bipolar junction transistor with adjustable gain in accordance with a second embodiment of the present invention.

FIG. 11 shows an illustrative diagram, indicating that the bipolar junction transistor is operating in a normal operating mode according to the FIG. 10 structural embodiment.

FIG. 12 shows an illustrative diagram, indicating that the bipolar junction transistor is operating in a positive surged operating mode according to the FIG. 10 structural embodiment.

FIG. 13 shows an illustrative diagram, indicating that the bipolar junction transistor is operating in a negative surged operating mode according to the FIG. 10 structural embodiment.

FIG. 14 schematically shows a structural diagram of a proposed bipolar junction transistor with adjustable gain in accordance with a third embodiment of the present invention.

FIG. 15 schematically shows a structural diagram of a proposed bipolar junction transistor with adjustable gain in accordance with a fourth embodiment of the present invention.

FIG. 16 schematically shows a structural diagram of a proposed bipolar junction transistor with adjustable gain in accordance with a fifth embodiment of the present invention.

FIG. 17 schematically shows a structural diagram of a proposed bipolar junction transistor with adjustable gain in accordance with a sixth embodiment of the present invention.

FIG. 18 schematically shows a structural diagram of a proposed bipolar junction transistor with adjustable gain in accordance with a seventh embodiment of the present invention.

FIG. 19 schematically shows a structural diagram of a proposed bipolar junction transistor with adjustable gain in accordance with an eighth embodiment of the present invention.

FIG. 20 schematically shows an exemplary diagram illustrating the technical characteristics of the proposed bipolar junction transistor with adjustable gain in accordance with the embodiments of the present invention.

### DESCRIPTION OF THE PREFERRED EMBODIMENTS

Reference will now be made in detail to the preferred embodiments of the present invention, examples of which are illustrated in the accompanying drawings. Wherever possible, the same reference numbers are used in the drawings and the description to refer to the same or like parts. In the drawings, the shape and thickness may be exaggerated for clarity and convenience. This description will be directed in particular to elements forming part of, or cooperating more directly with, methods and apparatus in accordance with the present disclosure. It is to be understood that elements not specifically shown or described may take various forms well known to those skilled in the art. Many alternatives and modifications will be apparent to those skilled in the art, once informed by the present disclosure.

The embodiments described below are illustrated to demonstrate the technical contents and characteristics of the present invention and to enable the persons skilled in the art to understand, make, and use the present invention. However, it shall be noticed that it is not intended to limit the scope of the present invention. Therefore, any equivalent modification or variation according to the spirit of the present invention is to be also included within the scope of the present invention.

Unless otherwise specified, some conditional sentences or words, such as “can”, “could”, “might”, or “may”, usually attempt to express that the embodiment in the invention has, but it can also be interpreted as a feature, element, or step that may not be needed. In other embodiments, these features, elements, or steps may not be required.

Reference throughout this specification to “one embodiment” or “an embodiment” means that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment.

Certain terms are used throughout the description and the claims to refer to particular components. One skilled in the art appreciates that a component may be referred to as different names. This disclosure does not intend to distinguish between components that differ in name but not in function. In the description and in the claims, the term “comprise” is used in an open-ended fashion, and thus should be interpreted to mean “include, but not limited to.” The phrases “be coupled to,” “couples to,” and “coupling to” are intended to compass any indirect or direct connection. Accordingly, if this disclosure mentioned that a first device is coupled with a second device, it means that the first device may be directly or indirectly connected to the second device through electrical connections, wireless communications, optical communications, or other signal connections with/without other intermediate devices or connection means.

The invention is particularly described with the following examples which are only for instance. Those skilled in the art will readily observe that numerous modifications and alterations of the device and method may be made while retaining the teachings of the invention. Accordingly, the following disclosure should be construed as limited only by the metes and bounds of the appended claims. In the whole patent application and the claims, except for clearly described content, the meaning of the article “a” and “the” includes the meaning of “one or at least one” of the element or component. Moreover, in the whole patent application and the claims, except that the plurality can be excluded obviously according to the context, the singular articles also contain the description for the plurality of elements or components. In the entire specification and claims, unless the contents clearly specify the meaning of some terms, the meaning of the article “wherein” includes the meaning of the articles “wherein” and “whereon”. The meanings of every term used in the present claims and specification refer to a usual meaning known to one skilled in the art unless the meaning is additionally annotated. Some terms used to describe the invention will be discussed to guide practitioners about the invention. Every example in the present specification cannot limit the claimed scope of the invention.

The terms “substantially,” “around,” “about” and “approximately” can refer to within 20% of a given value or range, and preferably within 10%. Besides, the quantities provided herein can be approximate ones and can be described with the aforementioned terms if are without being specified. When a quantity, density, or other parameters includes a specified range, preferable range or listed ideal values, their values can be viewed as any number within the given range.

As the Applicants have described earlier in the Description of the Prior Art, in order to effectively suppress the leakage current issue which mostly occurred in the conventional unidirectional or bidirectional bipolar junction transistor structure and meanwhile to maintain a relatively superior electrostatic discharge (ESD) protection efficiency, it is aimed to provide the present invention, which will be thus disclosed and taught to solve such drawbacks by proposing a novel and inventive bipolar junction transistor structure. The Applicants of the Application propose a novel bipolar junction transistor structure, which is characterized by having an adjustable gain, as disclosed in the present invention. The provided bipolar junction transistor with adjustable gain will now be provided and illustrated by a plurality of variant embodiments as described in the following sections for references.

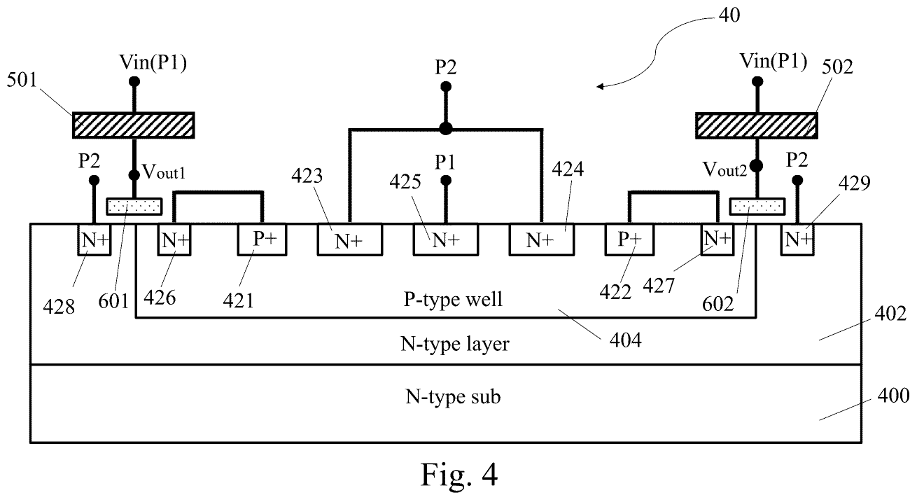

At first, please refer to FIG. 4, which schematically shows a structural diagram of a proposed bipolar junction transistor with adjustable gain in accordance with a first embodiment of the present invention. According to the present invention, the proposed bipolar junction transistor with adjustable gain 40 includes a semiconductor substrate 400, a doped layer 402, a doped well region 404, a first heavily doped region 421, a second heavily doped region 422, a third heavily doped region 423, a fourth heavily doped region 424, a fifth heavily doped region 425, a sixth heavily doped region 426, a seventh heavily doped region 427, an eighth heavily doped region 428 and a ninth heavily doped region 429. According to the first embodiment of the present invention, the semiconductor substrate 400 has a first conductivity type. And, the doped layer 402 has the first conductivity type and is formed on the semiconductor substrate 400. The doped well region 404, on the contrary, has a second conductivity type, which is opposite to the first conductivity type of the semiconductor substrate 400 and the doped layer 402. And, the doped well region 404 of the second conductivity type is formed in the doped layer 402 of the first conductivity type. According to the first embodiment as illustrated in the FIG. 4 structural scheme, it is illustrative that the first conductivity type can be an N type, while the second conductivity type will be a P type. As a result, under such a circumstance, as can be seen in FIG. 4, the semiconductor substrate 400 of the first conductivity type is an N-type substrate and is illustrated as an “N-type sub”, and the doped layer 402 of the first conductivity type, which is formed on the semiconductor substrate 400 of the first conductivity type is an N-type doped layer and is illustrated as an “N-type layer”. As for when the second conductivity type is a P type, then the doped well region 404 of the second conductivity type will be a P-type doped well region and is illustrated as a “P-type well”.

In addition, according to the first embodiment of the present invention as shown in FIG. 4, the first heavily doped region 421 has the second conductivity type, the second heavily doped region 422 has the second conductivity type, the third heavily doped region 423 has the first conductivity type, the fourth heavily doped region 424 has the first conductivity type, the fifth heavily doped region 425 has the first conductivity type, the sixth heavily doped region 426 has the first conductivity type, the seventh heavily doped region 427 has the first conductivity type, the eighth heavily doped region 428 has the first conductivity type and the ninth heavily doped region 429 has the first conductivity type. As a result, according to such conductivity type configuration, it is shown that the first heavily doped region 421 of the second conductivity type is a P-type heavily doped region and is illustrated as a “P+” in FIG. 4. Similarly, the second heavily doped region 422 of the second conductivity type is a P-type heavily doped region and is illustrated as a “P+” as well. The third heavily doped region 423 of the first conductivity type, the fourth heavily doped region 424 of the first conductivity type, the fifth heavily doped region 425 of the first conductivity type, the sixth heavily doped region 426 of the first conductivity type, the seventh heavily doped region 427 of the first conductivity type, the eighth heavily doped region 428 of the first conductivity type and the ninth heavily doped region 429 of the first conductivity type, on the contrary, are N-type heavily doped regions and each of them is illustrated as an “N+” in FIG. 4 embodiment.

According to the first embodiment as shown in FIG. 4, the first heavily doped region 421 of the second conductivity type (P+) and the second heavily doped region 422 of the second conductivity type (P+) are spaced apart by the third heavily doped region 423 of the first conductivity type (N+), the fourth heavily doped region 424 of the first conductivity type (N+) and the fifth heavily doped region 425 of the first conductivity type (N+).

The sixth heavily doped region 426 of the first conductivity type (N+) is electrically connected with the first heavily doped region 421 of the second conductivity type (P+), and the seventh heavily doped region 427 of the first conductivity type (N+) is electrically connected with the second heavily doped region 422 of the second conductivity type (P+). Meanwhile, the sixth heavily doped region 426 of the first conductivity type (N+), the first heavily doped region 421 of the second conductivity type (P+), the third heavily doped region 423 of the first conductivity type (N+), the fourth heavily doped region 424 of the first conductivity type (N+), the fifth heavily doped region 425 of the first conductivity type (N+), the second heavily doped region 422 of the second conductivity type (P+), and the seventh heavily doped region 427 of the first conductivity type (N+) are disposed in the doped well region 404 of the second conductivity type (P-type well). On the other hand, in the first embodiment of the present invention of FIG. 4, the eighth heavily doped region 428 of the first conductivity type (N+) and the ninth heavily doped region 429 of the first conductivity type (N+) are disposed in the doped layer 402 of the first conductivity type (N-type layer).

The fifth heavily doped region 425 of the first conductivity type (N+) is electrically coupled with a first pin P1. And, the third heavily doped region 423 of the first conductivity type (N+) and the fourth heavily doped region 424 of the first conductivity type (N+) are electrically connected in common and coupled with a second pin P2. Moreover, the eighth heavily doped region 428 of the first conductivity type (N+) which is disposed adjacent to the sixth heavily doped region 426, and the ninth heavily doped region 429 of the first conductivity type (N+) which is disposed adjacent to the seventh heavily doped region 427 are coupled with the second pin P2 as well.

According to the technical solution disclosed in the present invention, the present invention is aimed to provide at least detection circuit, in order to implement the bipolar junction transistor having adjustable gain. As can be seen in FIG. 4, a first detection circuit 501 is provided and disposed between the sixth heavily doped region 426 and the eighth heavily doped region 428, and a second detection circuit 502 is provided and disposed between the seventh heavily doped region 427 and the ninth heavily doped region 429. Each of the first detection circuit 501 and the second detection circuit 502 is provided with an input voltage Vin, which is electrically coupled with the first pin P1, for being operable to respectively generate a first output voltage Vout1 and a second output voltage Vout2. In other words, according to the embodiment in FIG. 4, the input voltage Vin is electrically coupled with the first pin P1. As a result, the first detection circuit 501 receives the input voltage Vin and is operable to output a first output voltage Vout1 to a first conducting layer 601. And the second detection circuit 502 receives the input voltage Vin and is operable to output a second output voltage Vout2 to a second conducting layer 602.

The first conducting layer 601 is provided so as to receive the first output voltage Vout1 and is disposed between the sixth heavily doped region 426 and the eighth heavily doped region 428. In the same manner, the second conducting layer 602 is disposed between the seventh heavily doped region 427 and the ninth heavily doped region 429 and is provided so as to receive the second output voltage Vout2. By employing the first detection circuit 501 and the second detection circuit 502, it is believed that the current path generated when the input voltage Vin is given and varies under different operating conditions can be controlled and determined according to different operating conditions, such that the bipolar junction transistor having adjustable gain 40 as illustrated in FIG. 4 embodiment is obtained.

Regarding the transistor structural configurations, according to the present invention, either the first conducting layer 601 or the second conducting layer 602 can be implemented by using a poly or metal gate. And the present invention is not limited thereto.

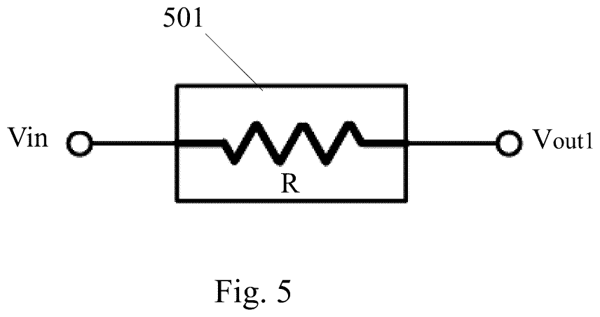

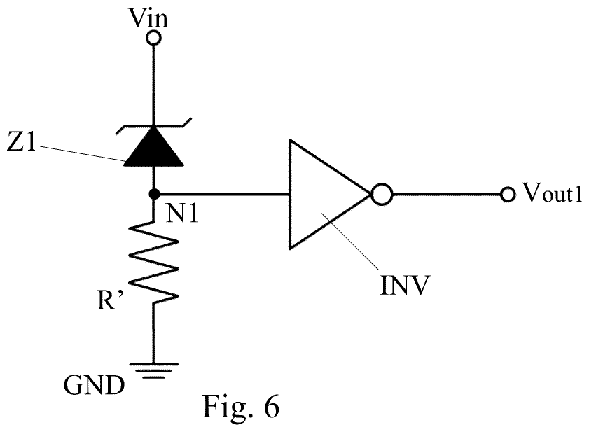

FIG. 5 and FIG. 6 show two feasible circuit diagrams for implementing the disclosed detection circuit of the present invention. Either the first detection circuit 501 or the second detection circuit 502 can be implemented by employing the circuit diagram as disclosed in FIG. 5 and in FIG. 6. The Applicants of the present invention merely take one of them, i.e. the first detection circuit 501, for detailed descriptions. And yet, the second detection circuit 502 can be implemented by applying the same manners. Since the circuit configurations are mostly the same, repeatedly descriptions are thus omitted in the following paragraphs.

Please refer to FIG. 5 first, in which FIG. 5 shows an illustrative structural diagram of a detection circuit according to one embodiment of the present invention when the detection circuit is a device or is a component. As can be seen, the first detection circuit 501 can be implemented by using a resistor R. And the resistor R may be contributed from a poly resistor or a well resistor in the transistor structure.

FIG. 6 shows another illustrative structural diagram of a detection circuit according to one another embodiment of the present invention when the detection circuit is a circuit diagram. As can be seen, the first detection circuit 501 may alternatively be implemented by comprising a Zener diode Z1, a resistor R′ and an inverter INV. As can be seen in FIG. 6, one end of the Zener diode Z1 is electrically connected with the input voltage Vin while another end of the Zener diode Z1 is connected with the resistor R′. Subsequently, the resistor R′ is further connected to a ground terminal GND. In addition, one end of the inverter INV is electrically connected with a joint end N1 where the Zener diode Z1 and the resistor R′ are connected while another end of the inverter INV is operable to generate the first output voltage Vout1. According to such an embodiment, it is controlled that a breakdown voltage of the Zener diode Z1 is greater than its reverse working maximum voltage (Vrwm). For instance, under a normal operating mode, the reverse working maximum voltage (Vrwm) of the Zener diode Z1 can be, for example, 3.3V or 5V.

In the following sections, the Applicants of the present invention proceed to provide the detailed descriptions of the technical contents explaining the generated current path when the input voltage Vin varies under different operating conditions so as to make the disclosed bipolar junction transistor of the present invention have an adjustable gain. The transistor structure in FIG. 4 of the first embodiment of the present invention, and the detection circuit implemented by using a resistor as previously described in FIG. 5 are taken as illustrative examples for references. However, the present invention is not limited thereto. As the detection circuit implemented by using a Zener diode, a resistor and an inverter as introduced in FIG. 6 may also be practicable. And the present invention certainly covers the equality.

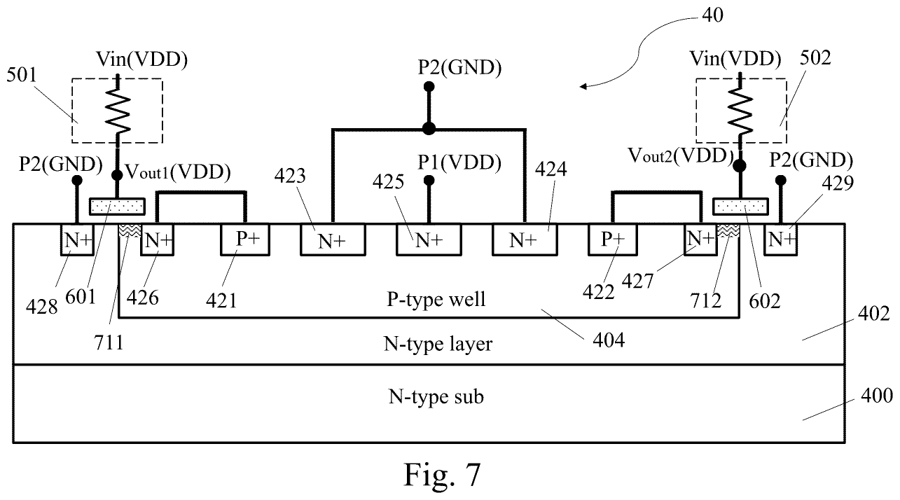

FIG. 7 shows an illustrative diagram, indicating that the bipolar junction transistor is operating in a normal operating mode according to the FIG. 4 structural embodiment. As can be seen, when the first conductivity type is an N type and the second conductivity type is a P type, then the first pin P1 is electrically coupled to a high voltage level (for example, VDD) and the second pin P2 is electrically coupled to a low voltage level (for example, GND), respectively.

Under such an operating mode when the input voltage Vin is coupled with a power supply voltage VDD and the bipolar junction transistor is operating in a normal operating mode, it is derived that an inversion layer 711 is formed underneath the first conducting layer 601 and an inversion layer 712 is formed underneath the second conducting layer 602. At this time, the first detection circuit 501 and the second detection circuit 502 generate the first output voltage Vout1 and the second output voltage Vout2 as the power supply voltage VDD, respectively. In addition, on account of the generated inversion layers 711 and 712 being formed, it is derived that the doped layer 402 (N-type layer) and the doped well region 404 (P-type well) are electrically tied in common such that the gain of the bipolar junction transistor is lowered. According to the embodiment of the present invention, the doped layer 402 (N-type layer) and the doped well region 404 (P-type well) can be electrically tied in common to a certain voltage value, for example, a ground voltage, a predetermined voltage level, or the like. The present invention is not limited thereto.

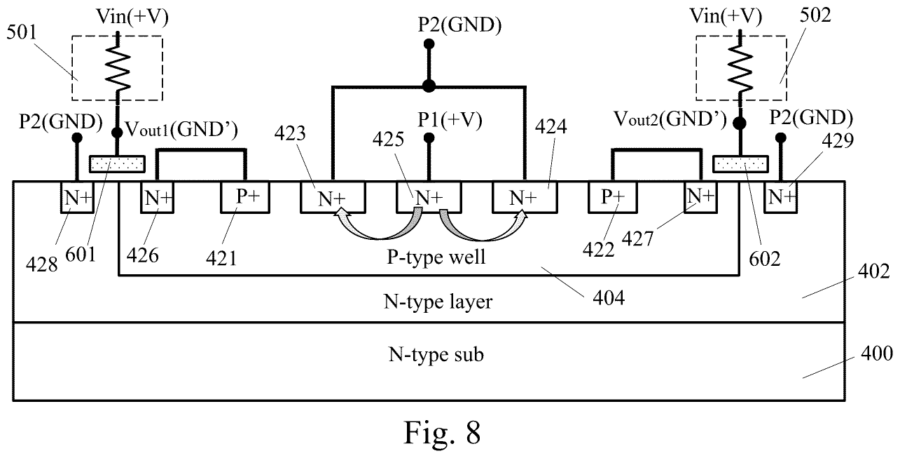

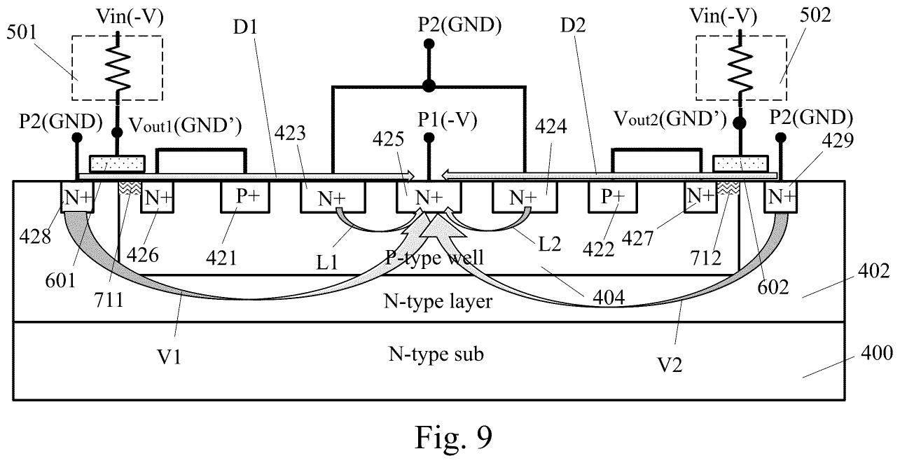

On the contrary, please refer to FIG. 8 and FIG. 9, in which there is a transient event taking place. FIG. 8 shows an illustrative diagram, indicating that the bipolar junction transistor is operating in a positive surged operating mode according to the FIG. 4 structural embodiment when the first pin P1 and the input voltage Vin are coupled with a positive voltage level +V. And, FIG. 9 shows an illustrative diagram, indicating that the bipolar junction transistor is operating in a negative surged operating mode according to the FIG. 4 structural embodiment when the first pin P1 and the input voltage Vin are coupled with a negative voltage level −V. As can be seen in FIG. 8, due to the RC time delay generated at the node where the first output voltage Vout1 and the second output voltage Vout2 are output, it is derived that the first detection circuit 501 and the second detection circuit 502 generate the first output voltage Vout1 and the second output voltage Vout2 as a virtual ground voltage GND′. Under such a condition when the positive surged operating mode is applied as illustrated in FIG. 8, no inversion layer is generated, and the current paths generated in the bipolar junction transistor includes at least one lateral conducting path of at least one lateral n-p-n bipolar junction transistor structure which is hereinafter, demonstrated as in arrows in FIG. 8. As can be seen, the lateral conducting path of the lateral n-p-n bipolar junction transistor structures is constructed by from the fifth heavily doped region 425 of the first conductivity type (N+), the doped well region 404 of the second conductivity type (P-type well) to the third heavily doped region 423 of the first conductivity type (N+), and also from the fifth heavily doped region 425 of the first conductivity type (N+), the doped well region 404 of the second conductivity type (P-type well) to the fourth heavily doped region 424 of the first conductivity type (N+). At this time, the bipolar junction transistor has an enhanced gain, which is higher than the gain when the bipolar junction transistor is operating in a normal operating mode as described in FIG. 7.

Furthermore, please refer to FIG. 9, in which the first pin P1 and the input voltage Vin are, on the other hand, coupled with the negative voltage level −V such that the bipolar junction transistor is operating in a negative surged operating mode. As can be seen, at this time, the first detection circuit 501 and the second detection circuit 502 generate the first output voltage Vout1 and the second output voltage Vout2 as the virtual ground voltage GND′. Under such a condition when the negative surged operating mode is applied as illustrated in FIG. 9, it can be seen that at least one inversion layer is generated, which includes the inversion layer 711 being formed underneath the first conducting layer 601 and the inversion layer 712 being formed underneath the second conducting layer 602. In addition, when the transient event is generated and applying the negative surged operating mode, it can be obtained that a plurality of current paths in the bipolar junction transistor in FIG. 9, which are hereinafter, demonstrated as in arrows in the drawing will be generated. And the plurality of current paths include at least one lateral conducting path of at least one lateral n-p-n bipolar junction transistor structure which is indicated by the current paths “L1” and “L2”, at least one vertical conducting path of at least one vertical n-p-n bipolar junction transistor structure which is indicated by the current paths “V1” and “V2”, as well as the diode conducting paths “D1” and “D2”. As can be seen in FIG. 9, when the bipolar junction transistor structure is operating in the negative surged operating mode, in addition to the lateral conducting paths of the lateral n-p-n bipolar junction transistor structure “L1” and “L2”, a plurality of more conducting paths including the vertical conducting paths of the vertical n-p-n bipolar junction transistor structure “V1” and “V2” and the diode conducting paths “D1” and “D2” are generated at the same time to further discharge the electrostatic discharge (ESD) currents when the transient event happens. At this time, the bipolar junction transistor has an enhanced gain, which is higher than the gain when the bipolar junction transistor is operating in a normal operating mode as described in FIG. 7.

As a result, to sum up, it is evident that according to the technical solution disclosed in the present invention, when there is a transient event taking place, such that the bipolar junction transistor is operating either in a positive surged operating mode or in a negative surged operating mode, the disclosed bipolar junction transistor has a higher gain than it is operating in a normal operating mode. And therefore, it is believed that the present invention effectively provides a bipolar junction transistor structure with adjustable gain. Moreover, according to the present invention, the unidirectional and bidirectional electrical characteristics of a bipolar junction transistor circuit scheme can be successfully integrated into the disclosed bipolar junction transistor with adjustable gain by employing the disclosed technical contents and corresponding electrical characteristics under different operating modes can be obtained at the same time.

Nevertheless, according to the present invention, the present invention is certainly not limited thereto such embodiment. According to alternative embodiments of the present invention, people who are skilled in the art and having ordinary understandings and technical backgrounds to the present invention would be allowed to make various modifications or changes depending on different circuit regulations and/or specifications without departing from the scope of the invention. And yet, the present invention still covers the modifications and its equality based on the disclosed technical contents of the present invention.

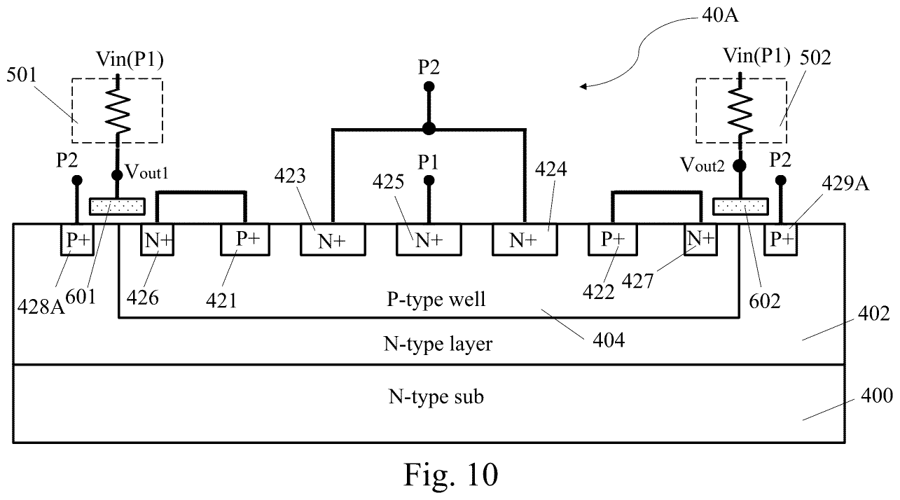

For instance, please refer to FIG. 10 for a second embodiment of the present invention. FIG. 10 schematically shows a structural diagram of a proposed bipolar junction transistor with adjustable gain in accordance with a second embodiment of the present invention. According to the second embodiment of the present invention, the proposed bipolar junction transistor with adjustable gain 40A includes a semiconductor substrate 400, a doped layer 402, a doped well region 404, a first heavily doped region 421, a second heavily doped region 422, a third heavily doped region 423, a fourth heavily doped region 424, a fifth heavily doped region 425, a sixth heavily doped region 426, a seventh heavily doped region 427, an eighth heavily doped region 428A and a ninth heavily doped region 429A. What differs from the first embodiment as provided in FIG. 4 is that, in the second embodiment of FIG. 10, the eighth heavily doped region 428A and the ninth heavily doped region 429A of the second embodiment have the second conductivity type. As a result, it can be seen that, in FIG. 10 the eighth heavily doped region 428A of the second conductivity type is a P-type heavily doped region and is illustrated as a “P+”. And the ninth heavily doped region 429A of the second conductivity type is a P-type heavily doped region and is illustrated as a “P+” as well.

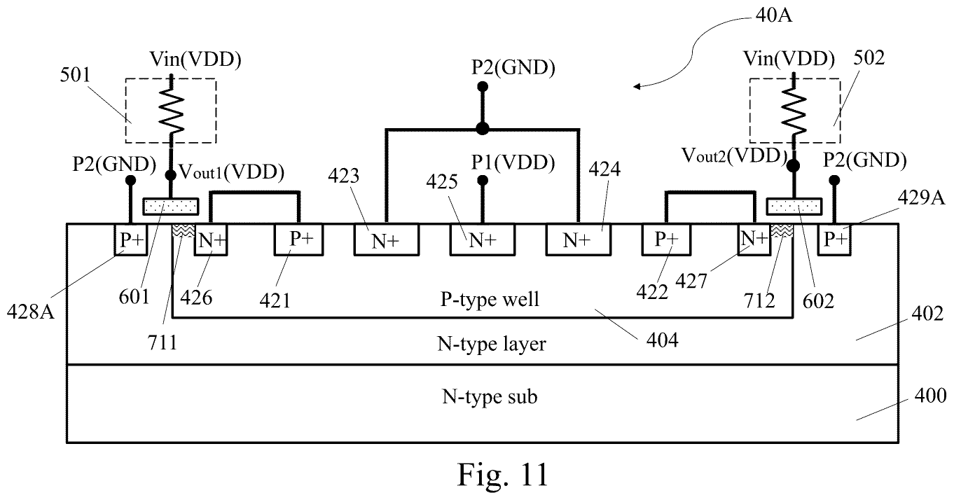

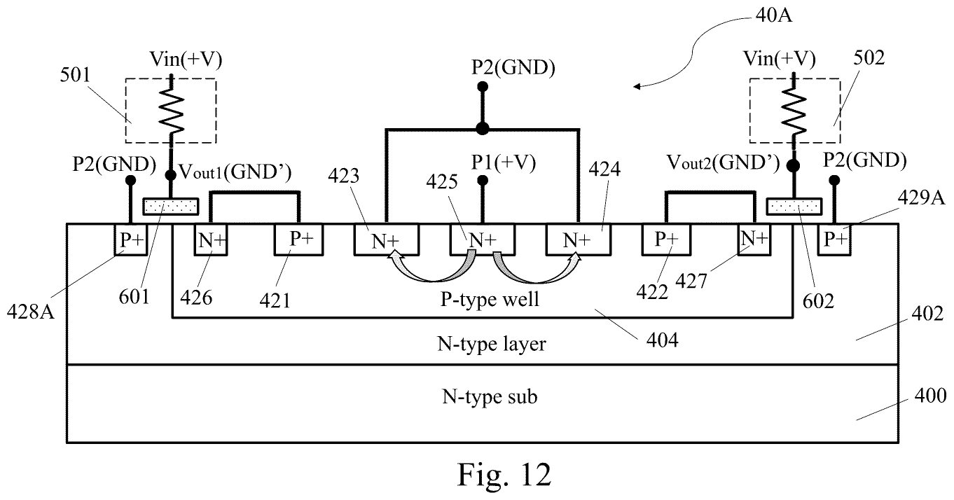

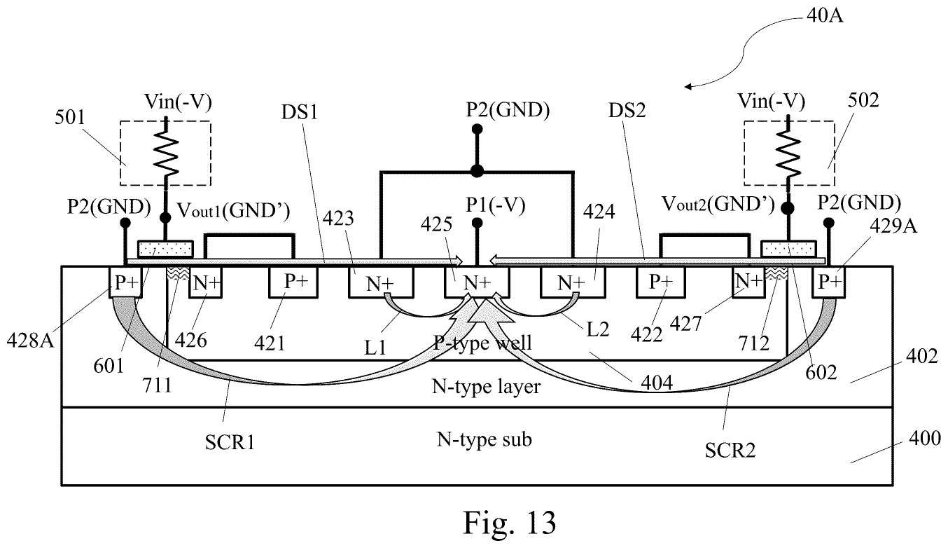

FIG. 11, FIG. 12 and FIG. 13 show illustrative diagrams, indicating that the bipolar junction transistor is operating under various operating modes according to the FIG. 10 structural embodiment. As can be seen, the first pin P1 is electrically coupled to a high voltage level (for example, VDD) and the second pin P2 is electrically coupled to a low voltage level (for example, GND), respectively.

Please refer to FIG. 11 first, in which the first pin P1 and the input voltage Vin are coupled with a power supply voltage VDD and the bipolar junction transistor is operating in a normal operating mode, under such a normal operating mode, it is obtained that the inversion layer 711 is formed underneath the first conducting layer 601 and the inversion layer 712 is formed underneath the second conducting layer 602. At this time, the first detection circuit 501 and the second detection circuit 502 generate the first output voltage Vout1 and the second output voltage Vout2 as the power supply voltage VDD, respectively. In addition, due to the generated inversion layers 711 and 712, it is also obtained that the doped layer 402 (N-type layer) and the doped well region 404 (P-type well) are electrically tied in common such that the gain of the bipolar junction transistor is lowered. According to the second embodiment of the present invention, the doped layer 402 (N-type layer) and the doped well region 404 (P-type well) can be electrically tied in common to a certain voltage value, for example, a predetermined voltage level, or the like. The present invention is not limited thereto.

In addition, FIG. 12 and FIG. 13 show illustrative circuit diagrams when a transient event occurs according to the FIG. 10 transistor structure. FIG. 12 indicates that the bipolar junction transistor 40A is operating in a positive surged operating mode when the first pin P1 and the input voltage Vin are coupled with a positive voltage level +V. And, FIG. 13, on the contrary shows an illustrative diagram, indicating that the bipolar junction transistor 40A is operating in a negative surged operating mode when the first pin P1 and the input voltage Vin are coupled with a negative voltage level −V.

As can be seen in FIG. 12, due to the RC time delay generated at the node where the first output voltage Vout1 and the second output voltage Vout2 are output, the first detection circuit 501 and the second detection circuit 502 generate the first output voltage Vout1 and the second output voltage Vout2 as a virtual ground voltage GND′. Under such a condition when the positive surged operating mode is applied as illustrated in FIG. 12, no inversion layer is generated, and the current paths generated in the bipolar junction transistor 40A includes at least one lateral conducting path of at least one lateral n-p-n bipolar junction transistor structure which is hereinafter, demonstrated as in arrows in FIG. 12. As can be seen, the lateral conducting path of the lateral n-p-n bipolar junction transistor structures is constructed by from the fifth heavily doped region 425 of the first conductivity type (N+), the doped well region 404 of the second conductivity type (P-type well) to the third heavily doped region 423 of the first conductivity type (N+), and also from the fifth heavily doped region 425 of the first conductivity type (N+), the doped well region 404 of the second conductivity type (P-type well) to the fourth heavily doped region 424 of the first conductivity type (N+). At this time, the bipolar junction transistor 40A has an enhanced gain, which is higher than the gain when the bipolar junction transistor is operating in a normal operating mode as described in FIG. 11.

Moreover, please proceed to refer to FIG. 13, in which the first pin P1 and the input voltage Vin are, on the other hand, coupled with the negative voltage level −V such that the bipolar junction transistor 40A is operating in a negative surged operating mode. As can be seen, at this time, the first detection circuit 501 and the second detection circuit 502 generate the first output voltage Vout1 and the second output voltage Vout2 as the virtual ground voltage GND′. Under such a condition when the negative surged operating mode is applied as illustrated in FIG. 13, it can be seen that at least one inversion layer is generated, which includes the inversion layer 711 being formed underneath the first conducting layer 601 and the inversion layer 712 being formed underneath the second conducting layer 602. In addition, when the transient event is generated and applying the negative surged operating mode, it can be obtained that a plurality of current paths in the bipolar junction transistor 40A in FIG. 13, which are hereinafter, demonstrated as in arrows in the drawing will be generated. And the plurality of generated current paths include at least one lateral conducting path of at least one lateral n-p-n bipolar junction transistor structure, which is indicated by the current paths “L1” and “L2”, and at least one vertical conducting path of at least one diode-like Silicon Controlled Rectifier (SCR) structure which is indicated by the current paths “SCR1” and “SCR2”, which are electrically parallelly connected with two diodes in series.

As can be seen, the lateral conducting path L1 of the lateral n-p-n bipolar junction transistor structures is constructed by from the third heavily doped region 423 of the first conductivity type (N+), the doped well region 404 of the second conductivity type (P-type well) to the fifth heavily doped region 425 of the first conductivity type (N+), and the lateral conducting path L2 of the lateral n-p-n bipolar junction transistor structures is constructed by from the fourth heavily doped region 424 of the first conductivity type (N+), the doped well region 404 of the second conductivity type (P-type well) to the fifth heavily doped region 425 of the first conductivity type (N+).

To be more specifically, the above mentioned at least one diode-like Silicon Controlled Rectifier (SCR) structure is a p-n-p-n silicon controlled rectifier structure, which is constructed from the eighth heavily doped region 428A of the second conductivity type (P+), the doped layer 402 of the first conductivity type (N-type layer), the doped well region 404 of the second conductivity type (P-type well), to the fifth heavily doped region 425 of the first conductivity type (N+), and also from the ninth heavily doped region 429A of the second conductivity type (P+), the doped layer 402 of the first conductivity type (N-type layer), the doped well region 404 of the second conductivity type (P-type well), to the fifth heavily doped region 425 of the first conductivity type (N+). The flowing current of the foregoing p-n-p-n silicon controlled rectifier structures is indicated by the current paths “SCR1” and “SCR2” in FIG. 13, and moreover, the flowing current of the two diodes in series, which is parallelly connected with the p-n-p-n silicon controlled rectifier structures, is indicated by the current paths “DS1” and “DS2” in the same figure.

As a result, as we can see from the embodiment as shown in FIG. 13, when the bipolar junction transistor structure 40A is operating in the negative surged operating mode, in addition to the lateral conducting path of the lateral n-p-n bipolar junction transistor structure “L1” and “L2”, a plurality of more conducting paths including the vertical conducting paths of the diode-like Silicon Controlled Rectifier (SCR) structure “SCR1” and “SCR2” and the diode conducting paths “DS1” and “DS2” are also generated at the same time to further discharge the electrostatic discharge (ESD) currents when the transient event happens. At this time, the bipolar junction transistor 40A is thus having an enhanced gain, which is higher than the gain when the bipolar junction transistor is operating in a normal operating mode as described in FIG. 11.

As a result, according to the second embodiment of the present invention, it may also be verified that according to the technical solution disclosed in the present invention, when there is a transient event taking place, such that the bipolar junction transistor is operating either in a positive surged operating mode or in a negative surged operating mode, the disclosed bipolar junction transistor structure is still implemented and characterized by having a higher gain than it is operating in a normal operating mode.

In the following paragraphs, the Applicants of the present invention proceed to further provide a plurality of more embodiments so as to verify that the disclosed bipolar junction transistor structure with adjustable gain is still effective and practicable in view of its several modifications and variations.

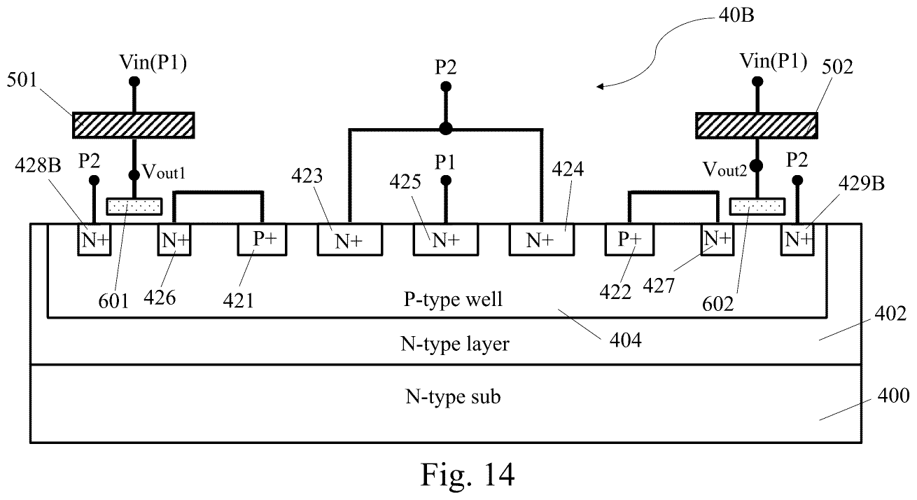

Please refer to FIG. 14 for a third embodiment of the present invention, in which FIG. 14 schematically shows a structural diagram of a proposed bipolar junction transistor with adjustable gain in accordance with a third embodiment of the present invention. According to the third embodiment of the present invention, the proposed bipolar junction transistor with adjustable gain 40B includes a semiconductor substrate 400, a doped layer 402, a doped well region 404, a first heavily doped region 421, a second heavily doped region 422, a third heavily doped region 423, a fourth heavily doped region 424, a fifth heavily doped region 425, a sixth heavily doped region 426, a seventh heavily doped region 427, an eighth heavily doped region 428B and a ninth heavily doped region 429B. According to the third embodiment of the present invention in FIG. 14, the eighth heavily doped region 428B, the sixth heavily doped region 426, the seventh heavily doped region 427 and the ninth heavily doped region 429B have the first conductivity type as the semiconductor substrate 400 and the doped layer 402 do, which is the N-type conductivity type. And each of the eighth heavily doped region 428B, the sixth heavily doped region 426, the seventh heavily doped region 427 and the ninth heavily doped region 429B of the first conductivity type is illustrated as an “N+” region in the third embodiment of FIG. 14.

According to the third embodiment as illustrated in FIG. 14, the eighth heavily doped region 428B, the sixth heavily doped region 426, the seventh heavily doped region 427 and the ninth heavily doped region 429B of the first conductivity type (N+) are commonly disposed in the doped well region 404 of the second conductivity type (P-type well) together with the first heavily doped region 421 of the second conductivity type (P+), the second heavily doped region 422 of the second conductivity type (P+), the third heavily doped region 423 of the first conductivity type (N+), the fourth heavily doped region 424 of the first conductivity type (N+) and the fifth heavily doped region 425 of the first conductivity type (N+). The first detection circuit 501 and the second detection circuit 502 can be provided with an input voltage Vin for being operable to respectively generate a first output voltage Vout1 and a second output voltage Vout2, and the first conducting layer 601 and the second conducting layer 602 can be disposed in the same manners as described in the previously disclosed first and second embodiments of the present invention such that the bipolar junction transistor 40B as illustrated in FIG. 14 embodiment is having adjustable gain as well. Similar technical descriptions are omitted and yet the present invention certainly covers the modified variation.

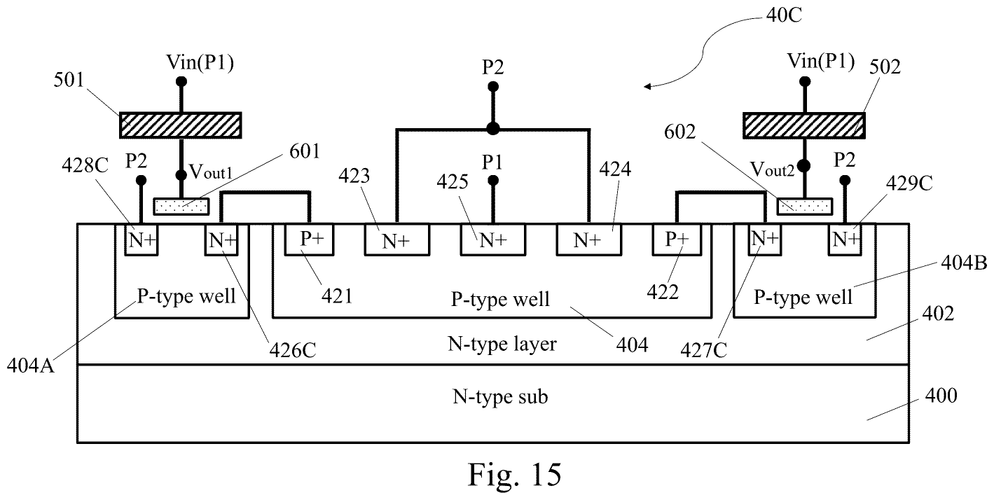

Furthermore, the circuit configurations are not limited thereto. Please refer to FIG. 15 for a fourth embodiment of the present invention, in which FIG. 15 schematically shows a structural diagram of a proposed bipolar junction transistor with adjustable gain in accordance with a fourth embodiment of the present invention. According to the fourth embodiment of the present invention, the proposed bipolar junction transistor with adjustable gain 40C includes a semiconductor substrate 400, a doped layer 402, a doped well region 404, a first heavily doped region 421, a second heavily doped region 422, a third heavily doped region 423, a fourth heavily doped region 424, a fifth heavily doped region 425, a sixth heavily doped region 426C, a seventh heavily doped region 427C, an eighth heavily doped region 428C and a ninth heavily doped region 429C. According to the fourth embodiment of the present invention in FIG. 15, the eighth heavily doped region 428C, the sixth heavily doped region 426C, the seventh heavily doped region 427C and the ninth heavily doped region 429C have the first conductivity type as the semiconductor substrate 400 and the doped layer 402 do, which is the N-type conductivity type. As such, it is evident that each of the eighth heavily doped region 428C, the sixth heavily doped region 426C, the seventh heavily doped region 427C and the ninth heavily doped region 429C having the first conductivity type is illustrated as a “N+” region in the fourth embodiment of FIG. 15.

The first heavily doped region 421 of the second conductivity type (P+), the second heavily doped region 422 of the second conductivity type (P+), the third heavily doped region 423 of the first conductivity type (N+), the fourth heavily doped region 424 of the first conductivity type (N+) and the fifth heavily doped region 425 of the first conductivity type (N+) are disposed in the doped well region 404 of the second conductivity type (P-type well). On the other hand, the eighth heavily doped region 428C of the first conductivity type (N+) and the sixth heavily doped region 426C of the first conductivity type (N+) are commonly disposed in a first doped well 404A of the second conductivity type (P-type well), and the seventh heavily doped region 427C of the first conductivity type (N+) and the ninth heavily doped region 429C of the first conductivity type (N+) are commonly disposed in a second doped well 404B of the second conductivity type (P-type well). In detailed configurations, the first doped well 404A of the second conductivity type (P-type well) and the second doped well 404B of the second conductivity type (P-type well) are disposed in the doped layer 402 of the first conductivity type (N-type layer), and the first doped well 404A of the second conductivity type (P-type well) and the second doped well 404B of the second conductivity type (P-type well) are isolated from the doped well region 404 of the second conductivity type (P-type well) accommodating the first heavily doped region 421 of the second conductivity type (P+), the second heavily doped region 422 of the second conductivity type (P+), the third heavily doped region 423 of the first conductivity type (N+), the fourth heavily doped region 424 of the first conductivity type (N+) and the fifth heavily doped region 425 of the first conductivity type (N+). According to the technical contents proposed in FIG. 15, such modified circuit configuration of the fourth embodiment can also be adopted for accomplishing the inventive effects of the present invention and implementing the bipolar junction transistor structure with adjustable gain.

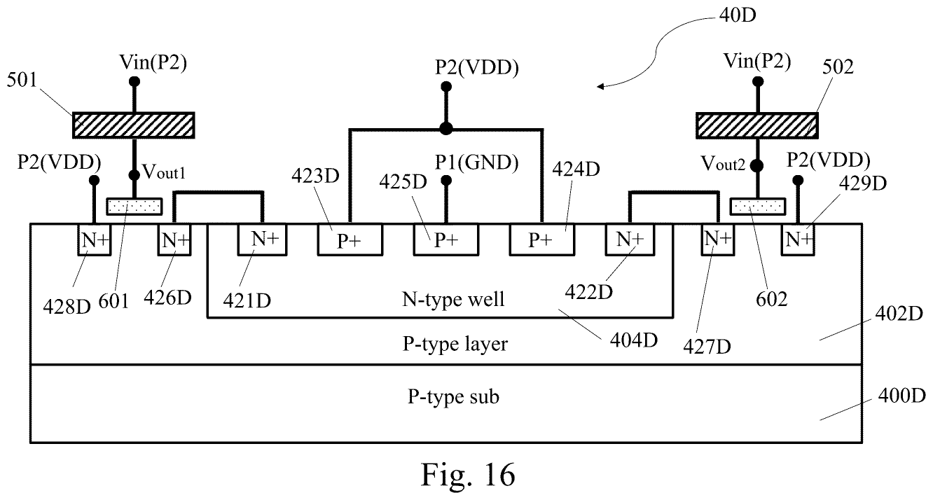

Moreover, according to the previously disclosed embodiments as illustrated in FIG. 4 to FIG. 15, it can be seen that when regarding the conductivity type to be configured in the proposed bipolar junction transistor structure, and when the first conductivity type is an N type, the second conductivity type will, on the other hand, be a P type. Optionally, according to the alternative embodiments of the present invention, then the first conductivity type may also be a P type, then the second conductivity type will alternatively be an N type. The present invention is not limited to the certain conductivity type to be disposed in the circuit diagram structure. And the alternative variations and embodiments may also be made by people who are skilled in the art and having ordinary skills of the art. For instance, please refer to FIG. 16 for a fifth embodiment of the present invention, in which FIG. 16 schematically shows a structural diagram of a proposed bipolar junction transistor with adjustable gain in accordance with a fifth embodiment of the present invention. According to the fifth embodiment of the present invention, the proposed bipolar junction transistor with adjustable gain 40D includes a semiconductor substrate 400D, a doped layer 402D, a doped well region 404D, a first heavily doped region 421D, a second heavily doped region 422D, a third heavily doped region 423D, a fourth heavily doped region 424D, a fifth heavily doped region 425D, a sixth heavily doped region 426D, a seventh heavily doped region 427D, an eighth heavily doped region 428D and a ninth heavily doped region 429D. According to the fifth embodiment of the present invention in FIG. 16, it is illustrative that the first conductivity type hereinafter is a P type, while the second conductivity type is an N type. As a result, under such a circumstance, as can be seen in FIG. 16, then the semiconductor substrate 400D of the first conductivity type is an P-type substrate and is illustrated as an “P-type sub”, and the doped layer 402D of the first conductivity type, which is formed on the semiconductor substrate 400D of the first conductivity type is an P-type doped layer and is illustrated as an “P-type layer”. As for when the second conductivity type is an N type, then the doped well region 404D of the second conductivity type will be an N-type doped well region and is illustrated as a “N-type well”.

In addition, according to the fifth embodiment of the present invention as shown in FIG. 16, the first heavily doped region 421D has the second conductivity type, the second heavily doped region 422D has the second conductivity type, the third heavily doped region 423D has the first conductivity type, the fourth heavily doped region 424D has the first conductivity type, the fifth heavily doped region 425D has the first conductivity type, the sixth heavily doped region 426D has the second conductivity type, the seventh heavily doped region 427D has the second conductivity type, the eighth heavily doped region 428D has the second conductivity type and the ninth heavily doped region 429D has the second conductivity type. As a result, according to such conductivity type configuration, it is shown that the first heavily doped region 421D of the second conductivity type is an N-type heavily doped region and is illustrated as an “N+” in FIG. 16. Similarly, the second heavily doped region 422D of the second conductivity type is an N-type heavily doped region and is illustrated as an “N+” as well. The third heavily doped region 423D of the first conductivity type, the fourth heavily doped region 424D of the first conductivity type, the fifth heavily doped region 425D of the first conductivity type, on the contrary, are P-type heavily doped regions and each of them is illustrated as a “P+” in FIG. 16 embodiment. In addition, the sixth heavily doped region 426D of the second conductivity type, the seventh heavily doped region 427D of the second conductivity type, the eighth heavily doped region 428D of the second conductivity type and the ninth heavily doped region 429D of the second conductivity type, are N-type heavily doped regions and each of them is illustrated as an “N+” in FIG. 16 embodiment. As can be seen, when the first conductivity type is a P type and the second conductivity type is an N type, then the first pin P1 and the second pin P2 are electrically coupled to a low voltage level (for example, GND) and to a high voltage level (for example, VDD), respectively. In the drawing, P1 (GND), P2 (VDD), and Vin (P2) respectively represents that the first pin P1 is electrically coupled to a ground voltage, the second pin P2 is electrically coupled to a power supply voltage VDD, and the input voltage Vin is electrically coupled to the second pin P2, hereinafter, as the input voltage Vin being electrically coupled to the power supply voltage VDD for detailed descriptions.

According to such an embodiment as shown in FIG. 16, the eighth heavily doped region 428D, the sixth heavily doped region 426D, the seventh heavily doped region 427D and the ninth heavily doped region 429D of the second conductivity type (N+) are commonly disposed in the doped layer 402D of the first conductivity type (P-type layer), while the first heavily doped region 421D of the second conductivity type (N+), the third heavily doped region 423D of the first conductivity type (P+), the fourth heavily doped region 424D of the first conductivity type (P+), the fifth heavily doped region 425D of the first conductivity type (P+) and the second heavily doped region 422D of the second conductivity type (N+) are commonly disposed in the doped well region 404D of the second conductivity type (N-type well). Such a variant embodiment as proposed in FIG. 16 is also practicable for implementing the inventive objectives of the present invention by forming the bipolar junction transistor with adjustable gain 40D when the first detection circuit 501, the second detection circuit 502 as well as the first conducting layer 601 and the second conducting layer 602 are employed.

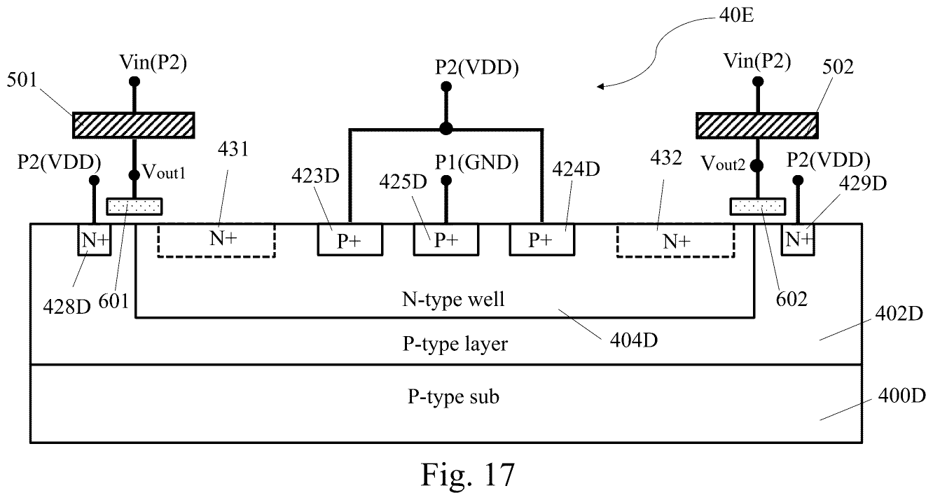

In addition, FIG. 17 shows another modified embodiment according to FIG. 16. As can be seen, FIG. 17 schematically shows a structural diagram of a proposed bipolar junction transistor with adjustable gain in accordance with a sixth embodiment of the present invention. According to the sixth embodiment of the present invention, the proposed bipolar junction transistor with adjustable gain 40E is a modified circuit scheme based on the bipolar junction transistor with adjustable gain 40D in FIG. 16. The differences are that, the sixth heavily doped region 426D of the second conductivity type (N+) can be alternatively merged into the first heavily doped region 421D of the second conductivity type (N+) and disposed in the doped well region 404D of the second conductivity type (N-type well). In the sixth embodiment as illustrated in FIG. 17, it is indicated by a first merged region 431 showing that the sixth heavily doped region 426D of the second conductivity type (N+) and the first heavily doped region 421D of the second conductivity type (N+) are merged. In the same manners, the seventh heavily doped region 427D of the second conductivity type (N+) can also be alternatively merged into the second heavily doped region 422D of the second conductivity type (N+) and disposed in the doped well region 404D of the second conductivity type (N-type well). A second merged region 432 is also configured so as to show that the seventh heavily doped region 427D of the second conductivity type (N+) and the second heavily doped region 422D of the second conductivity type (N+) are merged, while the eighth heavily doped region 428D of the second conductivity type (N+) and the ninth heavily doped region 429D of the second conductivity type (N+) are disposed in the doped layer 402D of the first conductivity type (P-type layer). Besides, it should be noted that, according to such embodiment as illustrated in FIG. 17, the first merged region 431 formed by merging the sixth heavily doped region 426D of the second conductivity type (N+) and the first heavily doped region 421D of the second conductivity type (N+) may be optional. And in the same manners, the second merged region 432 formed by merging the seventh heavily doped region 427D of the second conductivity type (N+) and the second heavily doped region 422D of the second conductivity type (N+) may also be optional. And according to such technical features, that is to say, the above-mentioned first merged region 431 and the second merged region 432 can be the optional heavily doped regions to be implemented. The present invention is certainly not limited thereto such configurations of the first merged region 431 and the second merged region 432 to be implemented. And it is believed that such a variant embodiment as proposed in FIG. 17 may also be practicable for implementing the inventive objectives of the present invention by forming the bipolar junction transistor with adjustable gain 40E when the first detection circuit 501, the second detection circuit 502 as well as the first conducting layer 601 and the second conducting layer 602 are employed.

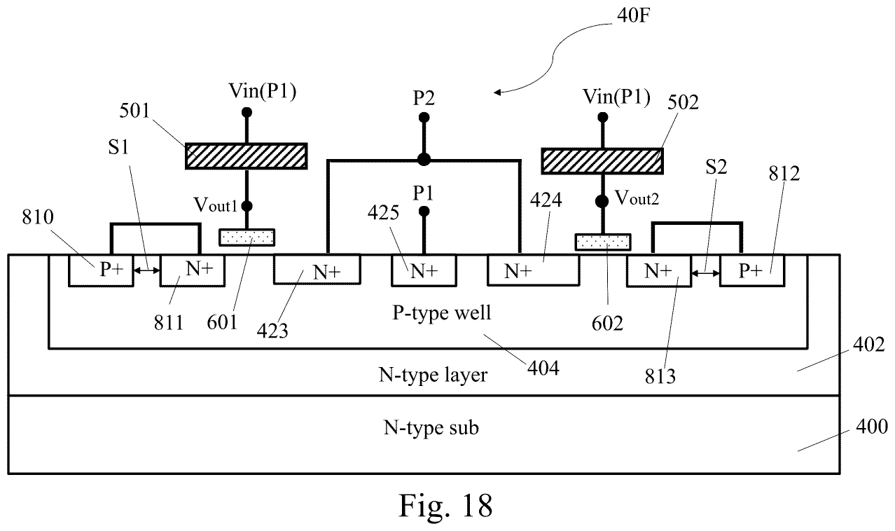

Moreover, the Applicants of the present invention, in the following paragraphs will be proposing a plurality of more variant embodiments which are applicable and feasible to implement the disclosed bipolar junction transistor structure which is characterized by having at least one detection circuit such that a gain of the provided bipolar junction transistor is adjustable under different operating conditions. Please refer to FIG. 18 for a seventh embodiment of the present invention. As can be seen, FIG. 18 schematically shows a structural diagram of a proposed bipolar junction transistor with adjustable gain in accordance with a seventh embodiment of the present invention. According to the seventh embodiment of the present invention, the proposed bipolar junction transistor with adjustable gain 40F is provided to include a semiconductor substrate 400, a doped layer 402, a doped well region 404, a third heavily doped region 423, a fourth heavily doped region 424, a fifth heavily doped region 425, a tenth heavily doped region 810, an eleventh heavily doped region 811, an twelfth heavily doped region 812 and a thirteenth heavily doped region 813. According to the seventh embodiment of the present invention in FIG. 18, it is illustrative that the first conductivity type is an N type and the second conductivity type is a P type. As a result, under such a circumstance, as can be seen in FIG. 18, the semiconductor substrate 400 of the first conductivity type is an N-type substrate and is illustrated as an “N-type sub”, and the doped layer 402 of the first conductivity type, which is formed on the semiconductor substrate 400 of the first conductivity type is an N-type doped layer and is illustrated as an “N-type layer”. As for when the second conductivity type is a P type, then the doped well region 404 of the second conductivity type will be a P-type doped well region and is illustrated as a “P-type well”.

In addition, the third heavily doped region 423 has the first conductivity type, the fourth heavily doped region 424 has the first conductivity type, the fifth heavily doped region 425 has the first conductivity type, the tenth heavily doped region 810 has the second conductivity type, the eleventh heavily doped region 811 has the first conductivity type, the twelfth heavily doped region 812 has the second conductivity type, and the thirteenth heavily doped region 813 has the first conductivity type. As a result, in the FIG. 18 embodiment, each of the third heavily doped region 423, the fourth heavily doped region 424, the fifth heavily doped region 425, the eleventh heavily doped region 811 and the thirteenth heavily doped region 813 is an N-type heavily doped region and each of them is illustrated as an “N+” region. On the contrary, the tenth heavily doped region 810 and the twelfth heavily doped region 812 of the second conductivity type are P-type heavily doped regions and each of them is illustrated as a “P+” region in FIG. 18.

According to the seventh embodiment in FIG. 18, the fifth heavily doped region 425 of the first conductivity type (N+) is electrically coupled with the first pin P1. And, the third heavily doped region 423 of the first conductivity type (N+) and the fourth heavily doped region 424 of the first conductivity type (N+) are electrically connected in common and coupled with the second pin P2. Moreover, the tenth heavily doped region 810 of the second conductivity type (P+) is electrically connected with the eleventh heavily doped region 811 of the first conductivity type (N+). And the twelfth heavily doped region 812 of the second conductivity type (P+) is electrically connected with the thirteenth heavily doped region 813 of the first conductivity type (N+). Meanwhile, the tenth heavily doped region 810 of the second conductivity type (P+), the eleventh heavily doped region 811 of the first conductivity type (N+), the third heavily doped region 423 of the first conductivity type (N+), the fifth heavily doped region 425 of the first conductivity type (N+), the fourth heavily doped region 424 of the first conductivity type (N+), the thirteenth heavily doped region 813 of the first conductivity type (N+) and the twelfth heavily doped region 812 of the second conductivity type (P+) are commonly disposed in the doped well region 404 of the second conductivity type (P-type well).

According to the technical solution disclosed in the present invention, the present invention is aimed to provide at least detection circuit, in order to implement the bipolar junction transistor having adjustable gain. As can be seen in FIG. 18, in the disclosed bipolar junction transistor with adjustable gain 40F, the first detection circuit 501 is provided and disposed between the eleventh heavily doped region 811 of the first conductivity type (N+) and the third heavily doped region 423 of the first conductivity type (N+), and the second detection circuit 502 is provided and disposed between the fourth heavily doped region 424 of the first conductivity type (N+) and the thirteenth heavily doped region 813 of the first conductivity type (N+). Each of the first detection circuit 501 and the second detection circuit 502 is provided with an input voltage Vin, and the input voltage Vin is electrically connected with the first pin P1, for being operable to respectively generate a first output voltage Vout1 and a second output voltage Vout2. In other words, the first detection circuit 501 receives the input voltage Vin and is operable to output a first output voltage Vout1 to a first conducting layer 601. And the second detection circuit 502 receives the input voltage Vin and is operable to output a second output voltage Vout2 to a second conducting layer 602.

The first conducting layer 601 is provided so as to receive the first output voltage Vout1 and is disposed between the eleventh heavily doped region 811 of the first conductivity type (N+) and the third heavily doped region 423 of the first conductivity type (N+). In the same manner, the second conducting layer 602 is disposed between the fourth heavily doped region 424 of the first conductivity type (N+) and the thirteenth heavily doped region 813 of the first conductivity type (N+) and is provided so as to receive the second output voltage Vout2. By employing the first detection circuit 501, the second detection circuit 502 as well as the first conducting layer 601 and the second conducting layer 602, it is believed that the current path generated when the input voltage Vin is given and varies under different operating conditions, including a normal operating mode, a positive surged operating mode and a negative surged operating mode under a transient event taking place, can be well controlled and determined according to different operating conditions. As a result, it is verified that the bipolar junction transistor having adjustable gain 40F as disclosed in FIG. 18 embodiment is obtained. Please refer to the foregoing embodiments for the similar technical descriptions, which are to be omitted herein the embodiment.

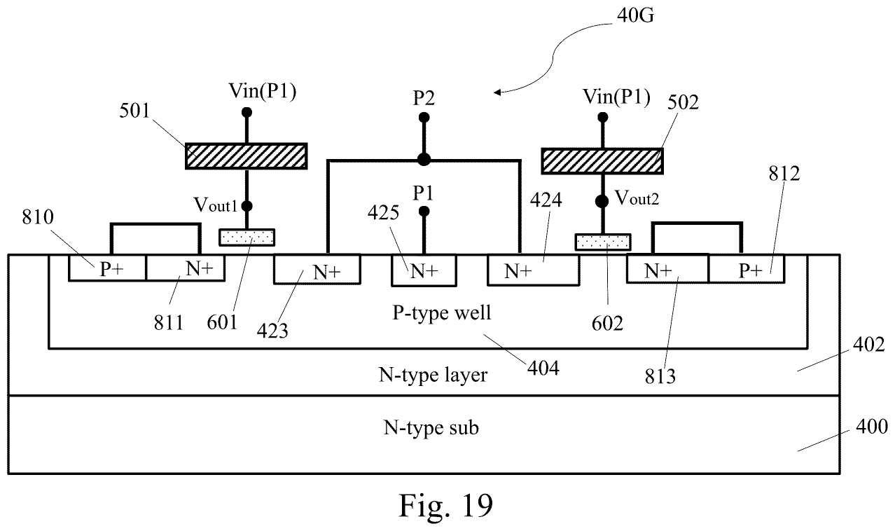

Similarly, please refer to FIG. 19 for another modified embodiment according to FIG. 18, in which FIG. 19 schematically shows a structural diagram of a proposed bipolar junction transistor with adjustable gain in accordance with an eighth embodiment of the present invention. According to the eighth embodiment of the present invention, the proposed bipolar junction transistor with adjustable gain 40G includes the semiconductor substrate 400, the doped layer 402, the doped well region 404, the third heavily doped region 423, the fourth heavily doped region 424, the fifth heavily doped region 425, the tenth heavily doped region 810, the eleventh heavily doped region 811, the twelfth heavily doped region 812 and the thirteenth heavily doped region 813 as described in the previously disclosed embodiment in FIG. 18. The difference is that, in order to further reduce the circuit layout area consumption, according to the eighth embodiment of the present invention in FIG. 19, then the first spacing S1 between the tenth heavily doped region 810 of the second conductivity type (P+) and the eleventh heavily doped region 811 of the first conductivity type (N+) (shown in FIG. 18) can be omitted. In the same manners, for achieving the same objective of reducing circuit layout area consumption, the second spacing S2 existing between the twelfth heavily doped region 812 of the second conductivity type (P+) and the thirteenth heavily doped region 813 of the first conductivity type (N+) (shown in FIG. 18) can be omitted as well. In general, according to the eighth embodiment of the present invention in FIG. 19, the tenth heavily doped region 810 of the second conductivity type (P+) and the eleventh heavily doped region 811 of the first conductivity type (N+) are disposed seamlessly adjacent to each other, and the twelfth heavily doped region 812 of the second conductivity type (P+) and the thirteenth heavily doped region 813 of the first conductivity type (N+) are disposed seamlessly adjacent to each other. And the present invention certainly covers the modifications and its equality based on the disclosed technical contents of the present invention regardless of the specific circuit layout configuration. And such embodiment is believed to be applicable to implement the objectives of the present invention for providing a bipolar junction transistor structure with adjustable gain as well.

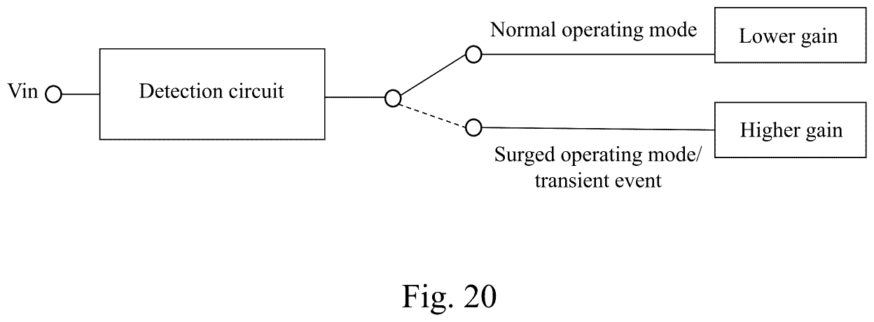

To sum up, it is evident that the present invention is aimed to disclose a bipolar junction transistor structure which is characterized by adopting at least one detection circuit such that a gain of the provided bipolar junction transistor is adjustable in view of a variety of different operating conditions. FIG. 20 schematically shows an exemplary diagram illustrating the technical characteristics of the proposed bipolar junction transistor with adjustable gain in accordance with the embodiments of the present invention. As can be seen, the at least one detection circuit, i.e. the first detection circuit 501 and the second detection circuit 502 as earlier disclosed in the present invention, is employed to receive the input voltage Vin and is operable to switch between a normal operating mode and a surged operating mode when a transient event occurs. When the proposed bipolar junction transistor is operating in the normal operating mode, the proposed bipolar junction transistor has a lower gain. While as for the proposed bipolar junction transistor being operating in the surged operating mode, the proposed bipolar junction transistor, on the contrary, has a higher gain. As a result, it is believed that by adopting the technical solution as disclosed in the plurality of embodiments of the present invention, a bipolar junction transistor structure having adjustable gain is sophisticatedly fabricated.

Moreover, according to the disclosed bipolar junction transistor structure having adjustable gain, when performing in the normal operating mode, the bipolar junction transistor structure shows electrical characteristics as a unidirectional device and having a lower gain and a reduced leakage current. In another aspect, when a transient event occurs and the bipolar junction transistor structure performs in a positive surged operating mode, then the bipolar junction transistor structure shows electrical characteristics as a bidirectional device and having a higher gain and a less V_{T} voltage (trigger voltage), so as to discharge the electrostatic discharge current more rapidly. In addition, when a transient event occurs and the bipolar junction transistor structure, on the other hand, is performing in a negative surged operating mode, then the bipolar junction transistor structure shows electrical characteristics as a unidirectional device again. Under such a negative surged operating mode, in addition to the original lateral conducting path, since two more conducting paths, including the vertical conducting path composed of at least one diode-like Silicon Controlled Rectifier (SCR) structure which are parallelly connected with two diodes in series, are formed, the disclosed bipolar junction transistor structure is advantageous of discharging the electrostatic discharge currents in a much more efficient manner. As a result, on account of all, it is believed that the proposed invention achieves in successfully integrating the unidirectional and bidirectional electrical characteristics in the disclosed bipolar junction transistor structure by employing the detection circuit such that the proposed bipolar junction transistor structure with adjustable gain is able to exhibit corresponding electrical characteristics under different operating conditions. In view of the plurality of embodiments as disclosed in the present invention, it is obvious that the present invention achieves to fabricate the disclosed bipolar junction transistor with adjustable gain in a plurality of beneficial merits, including low process fabrication cost, less circuit layout consumption, and reduced process complexity as well.

As a result, to sum up, according to the technical contents of the present invention, the Applicants of the present invention provide a plurality of feasible embodiments in the above-mentioned paragraphs for implementing the inventive effect of the invention for your references. It is apparent that, compared to the conventional prior arts, the present invention is characterized by providing a bipolar junction transistor structure having adjustable gain. As can be seen from the plurality of embodiments, it is obvious that the first pin P1 and the second pin P2 are configured and disposed on a same surface of the bipolar junction transistor structure. And thus, no backside metallization process is needed as it was required in the prior arts. As a result, it is believed that by employing the present invention, a plurality of more advantages including reducing the conventional process steps, fabrication cost and process complexity can be significantly accomplished at the same time.

The Applicants of the present invention have disclosed a plurality of applicable embodiments, which are advantageous of having extraordinary layout flexibility and can be composed of a variety of layout designs. Accordingly, in view of the technical contents and manners disclosed in the present invention without departing from the spirits of the present invention, it is believed that those skilled in the art and having general knowledge are able to make appropriate modifications or variations based on necessary circuit layout requirements, and the present invention is not restricted by the certain limited configurations and/or circuit diagrams as disclosed in the embodiments of the present invention. As a result, either the modifications or the variations should still fall into the scope of the present invention, and the present invention covers the modifications and its equality.

More specifically, according to the technical characteristics of the present invention which have been provided by the Applicants as illustrated in the previous paragraphs, it is obvious that the disclosed bipolar junction transistor structure with adjustable gain is effective. As can be seen from the embodiments, a great number of merits and advantages can be accomplished by adopting the present invention. Therefore, in view of all, it is obvious that the present invention is not only novel and inventive but also believed to be advantageous of solving and avoiding the conventional issues existing in the prior arts.

As a result, when compared to the prior arts, it is ensured that the present invention apparently shows much more effective performances than before. In addition, it is believed that the present invention is instinct, effective and highly competitive for IC technology and industries in the market nowadays, whereby having extraordinary availability and competitiveness for future industrial developments and being in condition for early allowance.

It will be apparent to those skilled in the art that various modifications and variations can be made to the present invention without departing from the scope or spirit of the invention. In view of the foregoing, it is intended that the present invention cover modifications and variations of this invention provided they fall within the scope of the invention and its equivalent.

What is claimed is:

1. A bipolar junction transistor with adjustable gain, comprising:
a semiconductor substrate of a first conductivity type;
a doped layer of the first conductivity type, which is formed on the semiconductor substrate of the first conductivity type;
a doped well region of a second conductivity type, which is formed in the doped layer of the first conductivity type, and the second conductivity type is opposite to the first conductivity type, wherein a first heavily doped region of the second conductivity type, a second heavily doped region of the second conductivity type, a third heavily doped region of the first conductivity type, a fourth heavily doped region of the first conductivity type and a fifth heavily doped region of the first conductivity type are further disposed in the doped well region of the second conductivity type, the fifth heavily doped region of the first conductivity type is electrically coupled with a first pin, the third heavily doped region of the first conductivity type and the fourth heavily doped region of the first conductivity type are electrically connected in common and coupled with a second pin, the first heavily doped region of the second conductivity type and the second heavily doped region of the second conductivity type are spaced apart by the third heavily doped region of the first conductivity type, the fourth heavily doped region of the first conductivity type and the fifth heavily doped region of the first conductivity type, and wherein the first heavily doped region of the second conductivity type is further electrically connected with a sixth heavily doped region and the second heavily doped region of the second conductivity type is further electrically connected with a seventh heavily doped region, and wherein an eighth heavily doped region which is disposed adjacent to the sixth heavily doped region and a ninth heavily doped region which is disposed adjacent to the seventh heavily doped region are coupled with the second pin; and
a first detection circuit disposed between the sixth heavily doped region and the eighth heavily doped region, and a second detection circuit disposed between the seventh heavily doped region and the ninth heavily doped region, wherein each of the first detection circuit and the second detection circuit is provided with an input voltage for being operable to respectively generate a first output voltage and a second output voltage, and wherein a first conducting layer receiving the first output voltage is disposed between the sixth heavily doped region and the eighth heavily doped region and a second conducting layer receiving the second output voltage is disposed between the seventh heavily doped region and the ninth heavily doped region for determining at least one current path when the input voltage varies under different operating conditions such that the bipolar junction transistor having adjustable gain is formed.

2. The bipolar junction transistor with adjustable gain according to claim 1, wherein when the first conductivity type is N type and the second conductivity type is P type, the first pin, the second pin, and the input voltage are electrically coupled to a high voltage level, a low voltage level, and the first pin, respectively.

3. The bipolar junction transistor with adjustable gain according to claim 2, wherein the eighth heavily doped region, the sixth heavily doped region, the seventh heavily doped region and the ninth heavily doped region have the first conductivity type, and the eighth heavily doped region, the sixth heavily doped region, the seventh heavily doped region and the ninth heavily doped region of the first conductivity type are disposed in the doped well region of the second conductivity type together with the first heavily doped region of the second conductivity type, the second heavily doped region of the second conductivity type, the third heavily doped region of the first conductivity type, the fourth heavily doped region of the first conductivity type and the fifth heavily doped region of the first conductivity type.

4. The bipolar junction transistor with adjustable gain according to claim 2, wherein the eighth heavily doped region, the sixth heavily doped region, the seventh heavily doped region and the ninth heavily doped region have the first conductivity type, the eighth heavily doped region of the first conductivity type and the sixth heavily doped region of the first conductivity type are disposed in a first doped well of the second conductivity type, the seventh heavily doped region of the first conductivity type and the ninth heavily doped region of the first conductivity type are disposed in a second doped well of the second conductivity type, the first doped well of the second conductivity type and the second doped well of the second conductivity type are disposed in the doped layer of the first conductivity type and are isolated from the doped well region of the second conductivity type accommodating the first heavily doped region of the second conductivity type, the second heavily doped region of the second conductivity type, the third heavily doped region of the first conductivity type, the fourth heavily doped region of the first conductivity type and the fifth heavily doped region of the first conductivity type.

5. The bipolar junction transistor with adjustable gain according to claim 2, wherein the eighth heavily doped region, the sixth heavily doped region, the seventh heavily doped region and the ninth heavily doped region have the first conductivity type, the sixth heavily doped region and the seventh heavily doped region of the first conductivity type are disposed in the doped well region of the second conductivity type together with the first heavily doped region of the second conductivity type, the second heavily doped region of the second conductivity type, the third heavily doped region of the first conductivity type, the fourth heavily doped region of the first conductivity type and the fifth heavily doped region of the first conductivity type, and the eighth heavily doped region of the first conductivity type and the ninth heavily doped region of the first conductivity type are disposed in the doped layer of the first conductivity type.

6. The bipolar junction transistor with adjustable gain according to claim 2, wherein the sixth heavily doped region and the seventh heavily doped region have the first conductivity type, the eighth heavily doped region and the ninth heavily doped region have the second conductivity type, the sixth heavily doped region and the seventh heavily doped region of the first conductivity type are disposed in the doped well region of the second conductivity type together with the first heavily doped region of the second conductivity type, the second heavily doped region of the second conductivity type, the third heavily doped region of the first conductivity type, the fourth heavily doped region of the first conductivity type and the fifth heavily doped region of the first conductivity type, and the eighth heavily doped region of the second conductivity type and the ninth heavily doped region of the second conductivity type are disposed in the doped layer of the first conductivity type.

7. The bipolar junction transistor with adjustable gain according to claim 1, wherein when the first conductivity type is P type and the second conductivity type is N type, the first pin, the second pin, and the input voltage are electrically coupled to a low voltage level, a high voltage level, and the second pin, respectively.

8. The bipolar junction transistor with adjustable gain according to claim 7, wherein the eighth heavily doped region, the sixth heavily doped region, the seventh heavily doped region and the ninth heavily doped region have the second conductivity type, and the eighth heavily doped region, the sixth heavily doped region, the seventh heavily doped region and the ninth heavily doped region of the second conductivity type are disposed in the doped layer of the first conductivity type.

9. The bipolar junction transistor with adjustable gain according to claim 7, wherein the eighth heavily doped region, the sixth heavily doped region, the seventh heavily doped region and the ninth heavily doped region have the second conductivity type, the eighth heavily doped region of the second conductivity type and the ninth heavily doped region of the second conductivity type are disposed in the doped layer of the first conductivity type, the sixth heavily doped region of the second conductivity type is alternatively merged into the first heavily doped region of the second conductivity type and disposed in the doped well region of the second conductivity type, and the seventh heavily doped region of the second conductivity type is alternatively merged into the second heavily doped region of the second conductivity type and disposed in the doped well region of the second conductivity type.

10. The bipolar junction transistor with adjustable gain according to claim 9, wherein a first merged region formed by merging the sixth heavily doped region of the second conductivity type and the first heavily doped region of the second conductivity type is optional.

11. The bipolar junction transistor with adjustable gain according to claim 9, wherein a second merged region formed by merging the seventh heavily doped region of the second conductivity type and the second heavily doped region of the second conductivity type is optional.

12. The bipolar junction transistor with adjustable gain according to claim 1, wherein either the first detection circuit or the second detection circuit is implemented by using a resistor.

13. The bipolar junction transistor with adjustable gain according to claim 1, wherein either the first detection circuit or the second detection circuit is implemented by comprising a Zener diode, a resistor and an inverter, one end of the Zener diode is electrically connected with the input voltage while another end of the Zener diode is connected with the resistor, the resistor is further connected to a ground terminal, and one end of the inverter is electrically connected with a joint end where the Zener diode and the resistor are connected while another end of the inverter is operable to generate the first output voltage or the second output voltage.

14. The bipolar junction transistor with adjustable gain according to claim 1, wherein when the input voltage is coupled with a power supply voltage (VDD), the first detection circuit and the second detection circuit generate the first output voltage and the second output voltage as the power supply voltage, and the bipolar junction transistor with adjustable gain has a first gain, and wherein when the input voltage is coupled with a positive voltage level so as to provide a positive surged operating mode, the first detection circuit and the second detection circuit generate the first output voltage and the second output voltage having a virtual ground voltage, and the bipolar junction transistor with adjustable gain has a second gain, where the second gain is greater than the first gain.

15. The bipolar junction transistor with adjustable gain according to claim 1, wherein when the input voltage is coupled with a power supply voltage (VDD), the first detection circuit and the second detection circuit generate the first output voltage and the second output voltage as the power supply voltage, and the bipolar junction transistor with adjustable gain has a first gain, and wherein when the input voltage is coupled with a negative voltage level so as to provide a negative surged operating mode, the first detection circuit and the second detection circuit generate the first output voltage and the second output voltage having a virtual ground voltage, and the bipolar junction transistor with adjustable gain has a second gain, where the second gain is greater than the first gain.

16. The bipolar junction transistor with adjustable gain according to claim 5, wherein when the input voltage is coupled with a power supply voltage (VDD), at least one inversion layer is formed underneath the first conducting layer and the second conducting layer.

17. The bipolar junction transistor with adjustable gain according to claim 5, wherein when the input voltage is coupled with a positive voltage level so as to provide a positive surged operating mode, the at least one current path comprises at least one lateral conducting path of at least one lateral n-p-n bipolar junction transistor structure which is constructed by from the fifth heavily doped region of the first conductivity type, the doped well region of the second conductivity type to the third heavily doped region of the first conductivity type, and from the fifth heavily doped region of the first conductivity type, the doped well region of the second conductivity type to the fourth heavily doped region of the first conductivity type.

18. The bipolar junction transistor with adjustable gain according to claim 5, wherein when the input voltage is coupled with a negative voltage level so as to provide a negative surged operating mode, at least one inversion layer is formed underneath the first conducting layer and the second conducting layer, and the at least one current path comprises at least one lateral conducting path of at least one lateral n-p-n bipolar junction transistor structure, at least one vertical conducting path of at least one vertical n-p-n bipolar junction transistor structure and at least one diode conducting path.

19. The bipolar junction transistor with adjustable gain according to claim 6, wherein when the input voltage is coupled with a power supply voltage (VDD), at least one inversion layer is formed underneath the first conducting layer and the second conducting layer.

20. The bipolar junction transistor with adjustable gain according to claim 6, wherein when the input voltage is coupled with a positive voltage level so as to provide a positive surged operating mode, the at least one current path comprises at least one lateral conducting path of at least one lateral n-p-n bipolar junction transistor structure which is constructed by from the fifth heavily doped region of the first conductivity type, the doped well region of the second conductivity type to the third heavily doped region of the first conductivity type, and from the fifth heavily doped region of the first conductivity type, the doped well region of the second conductivity type to the fourth heavily doped region of the first conductivity type.

21. The bipolar junction transistor with adjustable gain according to claim 6, wherein when the input voltage is coupled with a negative voltage level so as to provide a negative surged operating mode, at least one inversion layer is formed underneath the first conducting layer and the second conducting layer, and the at least one current path comprises at least one lateral conducting path of at least one lateral n-p-n bipolar junction transistor structure and at least one vertical conducting path of at least one diode-like Silicon Controlled Rectifier (SCR) structure which are parallelly connected with two diodes in series.

22. The bipolar junction transistor with adjustable gain according to claim 1, wherein either the first conducting layer or the second conducting layer is implemented by using a poly or metal gate.

23. A bipolar junction transistor with adjustable gain, comprising:
a semiconductor substrate of a first conductivity type;
a doped layer of the first conductivity type, which is formed on the semiconductor substrate of the first conductivity type;
a doped well region of a second conductivity type, which is formed in the doped layer of the first conductivity type, and the second conductivity type is opposite to the first conductivity type, wherein a third heavily doped region of the first conductivity type, a fourth heavily doped region of the first conductivity type, a fifth heavily doped region of the first conductivity type, a tenth heavily doped region of the second conductivity type, an eleventh heavily doped region of the first conductivity type, a twelfth heavily doped region of the second conductivity type and a thirteenth heavily doped region of the first conductivity type are further disposed in the doped well region of the second conductivity type, the fifth heavily doped region of the first conductivity type is electrically coupled with a first pin, the third heavily doped region of the first conductivity type and the fourth heavily doped region of the first conductivity type are electrically connected in common and coupled with a second pin, and wherein the tenth heavily doped region of the second conductivity type and the eleventh heavily doped region of the first conductivity type are electrically connected in common, the twelfth heavily doped region of the second conductivity type and the thirteenth heavily doped region of the first conductivity type are electrically connected in common, and wherein the tenth heavily doped region of the second conductivity type and the eleventh heavily doped region of the first conductivity type are disposed on one side of the third heavily doped region of the first conductivity type, the fourth heavily doped region of the first conductivity type and the fifth heavily doped region of the first conductivity type, and the twelfth heavily doped region of the second conductivity type and the thirteenth heavily doped region of the first conductivity type are disposed on an opposite side of the third heavily doped region of the first conductivity type, the fourth heavily doped region of the first conductivity type and the fifth heavily doped region of the first conductivity type; and
a first detection circuit disposed between the eleventh heavily doped region of the first conductivity type and the third heavily doped region of the first conductivity type, and a second detection circuit disposed between the thirteenth heavily doped region of the first conductivity type and the fourth heavily doped region of the first conductivity type, wherein each of the first detection circuit and the second detection circuit is provided with an input voltage for being operable to respectively generate a first output voltage and a second output voltage, and wherein a first conducting layer receiving the first output voltage is disposed between the eleventh heavily doped region of the first conductivity type and the third heavily doped region of the first conductivity type and a second conducting layer receiving the second output voltage is disposed between the thirteenth heavily doped region of the first conductivity type and the fourth heavily doped region of the first conductivity type for determining at least one current path when the input voltage varies under different operating conditions such that the bipolar junction transistor having adjustable gain is formed.

24. The bipolar junction transistor with adjustable gain according to claim 23, wherein the input voltage is electrically connected with the first pin.

25. The bipolar junction transistor with adjustable gain according to claim 23, wherein a first spacing is formed between the tenth heavily doped region of the second conductivity type and the eleventh heavily doped region of the first conductivity type.

26. The bipolar junction transistor with adjustable gain according to claim 23, wherein a second spacing is formed between the twelfth heavily doped region of the second conductivity type and the thirteenth heavily doped region of the first conductivity type.

27. The bipolar junction transistor with adjustable gain according to claim 23, wherein the tenth heavily doped region of the second conductivity type and the eleventh heavily doped region of the first conductivity type are disposed seamlessly adjacent to each other.

28. The bipolar junction transistor with adjustable gain according to claim 23, wherein the twelfth heavily doped region of the second conductivity type and the thirteenth heavily doped region of the first conductivity type are disposed seamlessly adjacent to each other.

29. The bipolar junction transistor with adjustable gain according to claim 23, wherein when the first conductivity type is N type and the second conductivity type is P type, the first pin, the second pin, and the input voltage are electrically coupled to a high voltage level, a low voltage level, and the first pin, respectively.

30. The bipolar junction transistor with adjustable gain according to claim 23, wherein when the first conductivity type is P type and the second conductivity type is N type, the first pin, the second pin, and the input voltage are electrically coupled to a low voltage level, a high voltage level, and the first pin, respectively.

31. The bipolar junction transistor with adjustable gain according to claim 23, wherein either the first detection circuit or the second detection circuit is implemented by using a resistor.

32. The bipolar junction transistor with adjustable gain according to claim 23, wherein either the first detection circuit or the second detection circuit is implemented by comprising a Zener diode, a resistor and an inverter, one end of the Zener diode is electrically connected with the input voltage while another end of the Zener diode is connected with the resistor, the resistor is further connected to a ground terminal, and one end of the inverter is electrically connected with a joint end where the Zener diode and the resistor are connected while another end of the inverter is operable to generate the first output voltage or the second output voltage.

33. The bipolar junction transistor with adjustable gain according to claim 23, wherein when the input voltage is coupled with a power supply voltage (VDD), the first detection circuit and the second detection circuit generate the first output voltage and the second output voltage as the power supply voltage, and the bipolar junction transistor with adjustable gain has a first gain, and wherein when the input voltage is coupled with a positive voltage level so as to provide a positive surged operating mode, the first detection circuit and the second detection circuit generate the first output voltage and the second output voltage having a virtual ground voltage, and the bipolar junction transistor with adjustable gain has a second gain, where the second gain is greater than the first gain.

34. The bipolar junction transistor with adjustable gain according to claim 23, wherein when the input voltage is coupled with a power supply voltage (VDD), the first detection circuit and the second detection circuit generate the first output voltage and the second output voltage as the power supply voltage, and the bipolar junction transistor with adjustable gain has a first gain, and wherein when the input voltage is coupled with a negative voltage level so as to provide a negative surged operating mode, the first detection circuit and the second detection circuit generate the first output voltage and the second output voltage having a virtual ground voltage, and the bipolar junction transistor with adjustable gain has a second gain, where the second gain is greater than the first gain.

35. The bipolar junction transistor with adjustable gain according to claim 23, wherein either the first conducting layer or the second conducting layer is implemented by using a poly or metal gate.
